(19) United States
(12) Patent Application Publication
(10) Pub. No.: US 2025/0362612 A1
(43) Pub. Date: Nov. 27, 2025

(54) RESIST UNDERLAYER COMPOSITION

(71) Applicant: Taiwan Semiconductor Manufacturing Co., Ltd., Hsinchu (TW)

(72) Inventors: Yen-Yu KUO, Hsinchu (TW); An-Ren ZI, Hsinchu (TW); Ching-Yu CHANG, Hsinchu (TW)

(73) Assignee: Taiwan Semiconductor Manufacturing Co., Ltd., Hsinchu (TW)

(21) Appl. No.: 19/294,716

(22) Filed: Aug. 8, 2025

Related U.S. Application Data
(63) Continuation of application No. 18/626,242, filed on Apr. 3, 2024.
(60) Provisional application No. 63/591,393, filed on Oct. 18, 2023.

(51) Int. Cl. G03F 7/11; C08L 43/04; H01L 21/027

(52) U.S. Cl. CPC G03F 7/11; C08L 43/04; H01L 21/0274

(57) ABSTRACT

A resist underlayer composition for extreme ultraviolet lithography is provided. The composition includes a first polymer, a second polymer, an acid generator and a solvent. The first polymer includes a first polymer backbone and an etching resistance enhancement unit covalently bonded to the first polymer backbone via a first linker. The etching resistance enhancement unit includes a silicon-containing unit including silicon-oxygen bonds or a metal-containing unit including metal-oxygen bonds. The second polymer includes a second polymer backbone and a crosslinker unit covalently bonded to the second polymer backbone via a second linker. The crosslinker unit includes one or more crosslinkable groups.

### PRIORITY CLAIM AND CROSS-REFERENCE

This application is a Continuation of U.S. application Ser. No. 18/626,242, filed Apr. 3, 2024, which claims the benefit of U.S. Provisional Patent Application No. 63/591,393, filed Oct. 18, 2023, each of which is incorporated by reference herein in its entirety.

### BACKGROUND

Semiconductor devices are used in a variety of electronic applications, such as personal computers, cell phones, digital cameras, and other electronic equipment. Semiconductor devices are fabricated by sequentially depositing dielectric layers, conductive layers, and semiconductor layers over a semiconductor substrate, and patterning the various material layers using photolithography. In a photolithography process, a photoresist is deposited over a substrate and is exposed to a radiation such as extreme ultraviolet (EUV) ray. The radiation exposure causes a chemical reaction in the exposed areas of the photoresist and creates a latent image corresponding to the mask pattern in the photoresist. The photoresist is next developed in a developer to remove either the exposed portions of the photoresist for a positive photoresist or the unexposed portions of the photoresist for a negative photoresist. The patterned photoresist is then used as an etch mask in subsequent etching processes in forming integrated circuits (ICs).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for fabricating a semiconductor device, in accordance with some embodiments of the disclosure.

FIGS. 2A-2H are cross-sectional views of a semiconductor device fabricated using the method of FIG. 1, in accordance with some embodiments of the disclosure.

FIG. 3A illustrates an embodiment of a resist underlayer composition included in a resist underlayer, in accordance with some embodiments of the disclosure.

FIG. 3B illustrates an exemplary copolymer in the resist underlayer composition, in accordance with some embodiments of the disclosure.

FIG. 4 illustrates exemplary silane and silsequioxane compounds.

FIG. 5 shows exemplary silicon-containing etching resistance enhancement units.

FIG. 6 shows an exemplary tin cage structure.

FIG. 7A illustrates exemplary organometallic compounds, in accordance with some embodiments.

FIG. 7B illustrates an exemplary reaction of an organometallic compound in the presence of water, in accordance with some embodiments.

FIG. 8 illustrates an exemplary reaction of organometallic compounds, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. System may be otherwise oriented (rotated 90 degrees or at other orientations) and the spatially relative descriptors used herein may likewise be interpreted accordingly.

When describing the compounds, compositions, methods and processes of the present disclosure, the following terms have the following meanings, unless otherwise indicated.

As described herein, the compounds disclosed herein may optionally be substituted with one or more substituents, such as illustrated generally below, or as exemplified by particular classes, subclasses, and species of the present disclosure. It will be appreciated that the phrase “optionally substituted” is used interchangeably with the phrase “substituted or unsubstituted”. In general, the term “substituted” whether proceeded by the term “optionally” or not, refers to the replacement of one or more hydrogen radicals in a given structure with the radical of a specified substituent. Unless otherwise indicated, an optionally substituted group may have a substituent at each substitutable position of the group. When more than one position in a given structure can be substituted with more than one substituent selected from a specified group, the substituent may be either the same or different at each position.

As used herein, the term “polymer” generally refers to a molecule composed of repeating structural units connected by covalent chemical bonds and characterized by a substantial number of repeating units (e.g., equal to or greater than 20 repeating units and often equal to or greater than 100 repeating units and often equal to or greater than 200 repeating units) and a number average molecular weight greater than or equal to 5,000 Daltons (Da) or 5 kDa, such as greater than or equal to 10 kDa, 15 kDa, 20 kDa, 30 kDa, 40 kDa, 50 kDa, or 100 kDa. Polymers are commonly the polymerization product of one or more monomer precursors. The term polymer includes homopolymers, i.e., polymers consisting of repeating units of a single monomer. The term polymer also includes copolymers which are formed when two or more different types of monomers are linked in the same polymer. Copolymers may comprise two or more monomer subunits, and include random, block, alternating, segmented, grafted, tapered and other copolymers. The term “crosslinked polymers” generally refers to polymers having one or multiple links between at least two polymer chains, which can result from multivalent monomers forming crosslinking sites upon polymerization.

As used herein, the term “group” may refer to a functional group of a chemical compound. Groups of the present compounds refer to an atom or a collection of atoms that are a part of the compound. Groups of the present disclosure may be attached to other atoms of the compound via one or more covalent bonds. Groups may also be characterized with respect to their valence state. The present disclosure includes groups characterized as monovalent, divalent, trivalent, etc. valence states.

As used herein, a wavy line in a chemical structure can be used to indicate a bond to the rest of the molecule. For example,

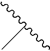

in, e.g.,

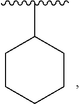 [SMILES: *C1CCCCC1]

is used to indicate that the given moiety, the cyclohexyl moiety in this example, is attached to a molecule via the bond that is “capped” with the wavy line.

As used herein, a “linker” refers to a contiguous chain of at least one atom, such as carbon, oxygen, nitrogen, sulfur, phosphorous, and combinations thereof, which connects a portion of a molecule to another portion of the same molecule or to a different molecule, moiety or solid support (e.g., microparticle). Linkers may connect the molecule via a covalent bond or other means, such as ionic or hydrogen bond interactions. In some embodiments, the linker is a heteroatomic linker (e.g., comprising 1-10 Si, N, O, P, or S atoms), a heteroalkylene (e.g., comprising 1-10 Si, N, O, P, or S atoms and an alkylene chain) or an alkylene linker (e.g., comprising 1-12 carbon atoms). In some embodiments, the linker may contain an ether (—O—), ester (—OC(═O)—), or carbonate (—OC(═O)O—) linkage.

“Hydroxy” or “hydroxyl” refers to the —OH group.

“Aromatic” or “aromatic group” as used herein refers to a major group of unsaturated cyclic hydrocarbons containing one or more rings. An aromatic group may contain carbon (C), nitrogen (N), oxygen (O), sulfur(S), boron (B), or any combination thereof. At least some carbon is included. Aromatic includes both aryl and heteroaryl rings.

“Aliphatic” or “aliphatic group” as used herein means a straight-chain or branched C₁₋₁₂ hydrocarbon chain that is completely saturated or that contains one or more units of unsaturation, or a monocyclic C₃₋₈ hydrocarbon or bicyclic C₈₋₁₂ hydrocarbon that is completely saturated or that contains one or more units of unsaturation, but which is not aromatic (also referred to herein as “cycloalkyl”), that has a single point of attachment to the rest of the molecule wherein any individual ring in said bicyclic ring system has 3-7 members. For example, suitable aliphatic groups include, but are not limited to, linear or branched alkyl, alkenyl, alkynyl groups and hybrids thereof such as (cycloalkyl)alkyl, (cycloalkenyl)alkyl or (cycloalkyl)alkenyl.

“Alkyl” refers to a straight or branched hydrocarbon chain group consisting solely of carbon and hydrogen atoms, containing no unsaturation, having from one to twelve carbon atoms (C₁-C₁₂ alkyl), one to eight carbon atoms (C₁-C₈ alkyl) or one to six carbon atoms (C₁-C₆ alkyl), and which is attached to the rest of the molecule by a single bond, e.g., methyl, ethyl, n-propyl, 1-methylethyl (iso-propyl), n-butyl, n-pentyl, 1,1-dimethylethyl (t-butyl), 3-methylhexyl, 2-methylhexyl, and the like. Unless stated otherwise specifically in the specification, alkyl groups are optionally substituted.

“Alkylene” or “alkylene chain” refers to a straight or branched divalent hydrocarbon chain linking the rest of the molecule to a radical group, consisting solely of carbon and hydrogen, containing no unsaturation, and having from one to twelve carbon atoms, e.g., methylene, ethylene, propylene, n-butylene, and the like. The alkylene chain is attached to the rest of the molecule through a single bond and to the radical group through a single bond. The points of attachment of the alkylene chain to the rest of the molecule and to the radical group can be through one carbon or any two carbons within the chain. Unless stated otherwise specifically in the specification, alkylene is optionally substituted.

“Alkenylene” or “alkenylene chain” refers to a straight or branched divalent hydrocarbon chain linking the rest of the molecule to a radical group, consisting solely of carbon and hydrogen, containing at least one carbon-carbon double bond and having from two to twelve carbon atoms, e.g., ethenylene, propenylene, n-butenylene, and the like. The alkenylene chain is attached to the rest of the molecule through a single bond and to the radical group through a double bond or a single bond. The points of attachment of the alkenylene chain to the rest of the molecule and to the radical group can be through one carbon or any two carbons within the chain. Unless stated otherwise specifically in the specification, alkenylene is optionally substituted.

“Alkynylene” or “alkynylene chain” refers to a straight or branched divalent hydrocarbon chain linking the rest of the molecule to a radical group, consisting solely of carbon and hydrogen, containing at least one carbon-carbon triple bond and having from two to twelve carbon atoms, e.g., ethynylene, propynylene, n-butynylene, and the like. The alkynylene chain is attached to the rest of the molecule through a single bond and to the radical group through a triple bond or a single bond. The points of attachment of the alkynylene chain to the rest of the molecule and to the radical group can be through one carbon or any two carbons within the chain. Unless stated otherwise specifically in the specification, alkynylene is optionally substituted.

“Alkoxy” refers to a group of the formula —ORₐ where Rₐ is an alkyl group as defined above containing one to twelve carbon atoms. Unless stated otherwise specifically in the specification, an alkoxy group is optionally substituted.

“Cycloalkyl” refers to a stable non-aromatic monocyclic or polycyclic carbocyclic ring, which may include fused or bridged ring systems, having from three to fifteen carbon atoms, preferably having from three to ten carbon atoms, and which is saturated or unsaturated and attached to the rest of the molecule by a single bond. Monocyclic cyclocalkyls include, for example, cyclopropyl, cyclobutyl, cyclopentyl, cyclohexyl, cycloheptly, and cyclooctyl. Polycyclic cycloalkyls include, for example, adamantyl, norbornyl, decalinyl, 7,7-dimethyl-bicyclo-[2.2.1]heptanyl, and the like. Unless stated otherwise specifically in the specification, a cycloalkyl group is optionally substituted.

“Heteroalkyl” refers to an alkyl group, as defined above, comprising at least one heteroatom (e.g., N, O, P or S) within the alkyl group or at a terminus of the alkyl group. In some embodiments, the heteroatom is within the alkyl group (i.e., the heteroalkyl comprises at least one carbon-[heteroatom]ₓ-carbon bond, where x is 1, 2 or 3). In other embodiments, the heteroatom is at a terminus of the alkyl group and thus serves to join the alkyl group to the remainder of the molecule (e.g., M1-H-A), where M1 is a portion of the molecule, H is a heteroatom and A is an alkyl group). Unless stated otherwise specifically in the specification, a heteroalkyl group is optionally substituted. Exemplary heteroalkyl groups include ethylene oxide (e.g., polyethylene oxide), optionally including phosphorous-oxygen bonds, such as phosphodiester bonds.

“Heteroalkylene” refers to an alkylene group, as defined above, comprising at least one heteroatom (e.g., N, O, P or S) within the alkylene chain or at a terminus of the alkylene chain. In some embodiments, the heteroatom is within the alkylene chain (i.e., the heteroalkylene comprises at least one carbon-[heteroatom]-carbon bond, where x is 1, 2 or 3). In other embodiments, the heteroatom is at a terminus of the alkylene and thus serves to join the alkylene to the remainder of the molecule (e.g., M1-H-A-M2, where M1 and M2 are portions of the molecule, H is a heteroatom and A is an alkylene). Unless stated otherwise specifically in the specification, a heteroalkylene group is optionally substituted.

“Heteroalkenylene” is a heteroalkylene, as defined above, comprising at least one carbon-carbon double bond. Unless stated otherwise specifically in the specification, a heteroalkenylene group is optionally substituted.

“Heteroalkynylene” is a heteroalkylene comprising at least one carbon-carbon triple bond. Unless stated otherwise specifically in the specification, a heteroalkynylene group is optionally substituted.

“Heteroatomic” in reference to a “heteroatomic linker” refers to a linker group consisting of one or more heteroatoms. Exemplary heteroatomic linkers include single atoms selected from the group consisting of O, N, P and S, and multiple heteroatoms for example a linker having the formula —P(O⁻)(═O)O— or —OP(O⁻)(═O)O— and multimers and combinations thereof.

“Aryl” refers to a ring system comprising at least one carbocyclic aromatic ring. In some embodiments, an aryl comprises from 6 to 18 carbon atoms. The aryl ring may be a monocyclic, bicyclic, tricyclic or tetracyclic ring system, which may include fused or bridged ring systems. Aryls include, but are not limited to, aryls derived from aceanthrylene, acenaphthylene, acephenanthrylene, anthracene, azulene, benzene, chrysene, fluoranthene, fluorene, as-indacene, s-indacene, indane, indene, naphthalene, phenalene, phenanthrene, pleiadene, pyrene, and triphenylene. Unless stated otherwise specifically in the specification, an aryl group is optionally substituted.

“Heteroaryl” refers to a 5- to 14-membered ring system comprising one to thirteen carbon atoms, one to six heteroatoms selected from the group consisting of nitrogen, oxygen and sulfur, and at least one aromatic ring. For purposes of certain embodiments of this disclosure, the heteroaryl radical may be a monocyclic, bicyclic, tricyclic or tetracyclic ring system, which may include fused or bridged ring systems; and the nitrogen, carbon or sulfur atoms in the heteroaryl radical may be optionally oxidized; the nitrogen atom may be optionally quaternized. Examples include, but are not limited to, azepinyl, acridinyl, benzimidazolyl, benzthiazolyl, benzindolyl, benzodioxolyl, benzofuranyl, benzooxazolyl, benzothiazolyl, benzothiadiazolyl, benzo[b][1,4]dioxepinyl, 1,4-benzodioxanyl, benzonaphthofuranyl, benzoxazolyl, benzodioxolyl, benzodioxinyl, benzopyranyl, benzopyranonyl, benzofuranyl, benzofuranonyl, benzothienyl (benzothiophenyl), benzotriazolyl, benzo[4,6]imidazo[1,2-a]pyridinyl, benzoxazolinonyl, benzimidazolthionyl, carbazolyl, cinnolinyl, dibenzofuranyl, dibenzothiophenyl, furanyl, furanonyl, isothiazolyl, imidazolyl, indazolyl, indolyl, indazolyl, isoindolyl, indolinyl, isoindolinyl, isoquinolyl, indolizinyl, isoxazolyl, naphthyridinyl, oxadiazolyl, 2-oxoazepinyl, oxazolyl, oxiranyl, 1-oxidopyridinyl, 1-oxidopyrimidinyl, 1-oxidopyrazinyl, 1-oxidopyridazinyl, 1-phenyl-1H-pyrrolyl, phenazinyl, phenothiazinyl, phenoxazinyl, phthalazinyl, pteridinyl, pteridinonyl, purinyl, pyrrolyl, pyrazolyl, pyridinyl, pyridinonyl, pyrazinyl, pyrimidinyl, pryrimidinonyl, pyridazinyl, pyrrolyl, pyrido[2,3-d]pyrimidinonyl, quinazolinyl, quinazolinonyl, quinoxalinyl, quinoxalinonyl, quinolinyl, isoquinolinyl, tetrahydroquinolinyl, thiazolyl, thiadiazolyl, thieno[3,2-d]pyrimidin-4-onyl, thieno[2,3-d]pyrimidin-4-onyl, triazolyl, tetrazolyl, triazinyl, and thiophenyl (i.e., thienyl). Unless stated otherwise specifically in the specification, a heteroaryl group is optionally substituted.

“Heterocyclic” refers to a stable 3- to 18-membered aromatic or non-aromatic ring comprising one to twelve carbon atoms and from one to six heteroatoms selected from the group consisting of nitrogen, oxygen and sulfur. Unless stated otherwise specifically in the specification, the heterocyclic ring may be a monocyclic, bicyclic, tricyclic or tetracyclic ring system, which may include fused or bridged ring systems; and the nitrogen, carbon or sulfur atoms in the heterocyclic ring may be optionally oxidized; the nitrogen atom may be optionally quaternized; and the heterocyclic ring may be partially or fully saturated. Examples of aromatic heterocyclic rings are listed below in the definition of heteroaryls (i.e., heteroaryl being a subset of heterocyclic). Examples of non-aromatic heterocyclic rings include, but are not limited to, dioxolanyl, thienyl[1,3]dithianyl, decahydroisoquinolyl, imidazolinyl, imidazolidinyl, isothiazolidinyl, isoxazolidinyl, morpholinyl, octahydroindolyl, octahydroisoindolyl, 2-oxopiperazinyl, 2-oxopiperidinyl, 2-oxopyrrolidinyl, oxazolidinyl, piperidinyl, piperazinyl, 4-piperidonyl, pyrrolidinyl, pyrazolidinyl, pyrazolopyrimidinyl, quinuclidinyl, thiazolidinyl, tetrahydrofuryl, trioxanyl, trithianyl, triazinanyl, tetrahydropyranyl, thiomorpholinyl, thiamorpholinyl, 1-oxo-thiomorpholinyl, and 1,1-dioxo-thiomorpholinyl. Unless stated otherwise specifically in the specification, a heterocyclic group is optionally substituted.

The term “substituted” used herein means any of the above groups wherein at least one hydrogen atom (e.g., 1, 2, 3 or all hydrogen atoms) is replaced by a bond to a non-hydrogen atoms such as, but not limited to: a halogen atom such as F, Cl, Br, and I; an oxygen atom in groups such as hydroxyl groups, alkoxy groups, and ester groups; a sulfur atom in groups such as thiol groups, thioalkyl groups, sulfone groups, sulfonyl groups, and sulfoxide groups; a nitrogen atom in groups such as amines, amides, alkylamines, dialkylamines, arylamines, alkylarylamines, diarylamines, N-oxides, imides, and enamines; a silicon atom in groups such as trialkylsilyl groups, dialkylarylsilyl groups, alkyldiarylsilyl groups, and triarylsilyl groups; and other heteroatoms in various other groups. “Substituted” also means any of the above groups in which one or more hydrogen atoms are replaced by a higher-order bond (e.g., a double- or triple-bond) to a heteroatom such as oxygen in oxo, carbonyl, carboxyl, and ester groups; and nitrogen in groups such as imines, oximes, hydrazones, and nitriles. For example, “substituted” includes any of the above groups in which one or more hydrogen atoms are replaced with —NR_{g}Rₕ, —NR_{g}C(═O)Rₕ, —NR_{g}C(═O)NR_{g}Rₕ, —NR_{g}C(═O)ORₕ, —NR_{g}SO₂Rₕ, —OC(═O)NR_{g}Rₕ, —OR_{g}, —SR_{g}, —SOR_{g}, —SO₂R_{g}, —OSO₂R_{g}, —SO₂OR_{g}, ═NSO₂R_{g}, and —SO₂NR_{g}Rₕ. “Substituted” also means any of the above groups in which one or more hydrogen atoms are replaced with —C(═O)R_{g}, —C(═O)OR_{g}, —C(═O)NR_{g}Rₕ, —CH₂SO₂R_{g}, and —CH₂SO₂NR_{g}Rₕ. In the foregoing, R_{g} and Rₕ are the same or different and independently hydrogen, alkyl, alkoxy, alkylamino, thioalkyl, aryl, aralkyl, cycloalkyl, cycloalkylalkyl, haloalkyl, heterocyclyl, N-heterocyclyl, heterocyclylalkyl, heteroaryl, N-heteroaryl and/or heteroarylalkyl. “Substituted” further means any of the above groups in which one or more hydrogen atoms are replaced by a bond to an amino, cyano, hydroxyl, imino, nitro, oxo, thioxo, halo, alkyl, alkoxy, alkylamino, thioalkyl, aryl, aralkyl, cycloalkyl, cycloalkylalkyl, haloalkyl, heterocyclyl, N-heterocyclyl, heterocyclylalkyl, heteroaryl, N-heteroaryl and/or heteroarylalkyl group. In addition, each of the foregoing substituents may also be optionally substituted with one or more of the above substituents.

IC fabrication uses one or more photolithography processes to transfer geometric patterns to a film or substrate. Geometric shapes and patterns on a semiconductor make up the complex structures that allow the dopants, electrical properties and wires to complete a circuit and fulfill a technological purpose. In a photolithography process, a photoresist is applied as a thin film to a substrate, and subsequently exposed to one or more types of radiation or light through a photomask. The photomask contains clear and opaque features that define a pattern which is to be created in the photoresist layer. Areas in the photoresist exposed to light transmitted through the photomask are made either soluble or insoluble in a specific type of solution known as a developer. In the case when the exposed regions are soluble, a positive image of the photomask is produced in the photoresist and this type of photoresist is called a positive photoresist. On the other hand, if the unexposed areas are dissolved by the developer, a negative image results in the photoresist and this type of photoresist is called a negative photoresist. The developer removes the more soluble areas, leaving the patterned photoresist in place. The resist pattern is then used as an etch mask in subsequent etching processes, transferring the pattern to an underlying material layer, thereby replicating the mask pattern in the underlying material layer.

Extreme ultraviolet (EUV) lithography extends lithography down to 32 nm and below regime by using short exposure wavelength in the range of 11 to 14 nm, generally 13.5 nm. EUV lithography uses a high performance photoresist with high sensitivity for cost reduction of the high-power exposure source, and to provide good resolution of the image. Metallic resists containing metals with high EUV photo absorption have been developed to improve the resist sensitivity to the EUV radiation, thereby lower exposure doses can be used for patterning the photoresist layer. Organometallic compounds having photo cleavable organic ligands bonded to the metals are used as precursors for EUV photoresist. These photo cleavable ligands are cleaved when exposed to radiation to generate radicals. Radicals generated from the metal core-ligand bond cleavage initiate and trigger polymerization, during which the metal core radical is first react with ambient water to form a metal hydroxide, and the subsequent condensation of metal hydroxides forms the metal-oxygen clusters.

EUV lithography uses reflective masks as no transparent materials are available to facilitate a transmission mask at EUV wavelength. Resist underlayers with high EUV photo absorption can improve resist performance such as sensitivity, imaging capability, dissolution contrast, resolution and process window. Beyond just lithography performance, as the resist underlayers also serve a dual function as an etch mask, the resist underlayers should offer sufficient etching resistance for transferring the resist pattern into the substrate.

Embodiments of the present disclosure provide resist underlayer compositions designed to absorb the EUV radiation used to expose the photoresist, thereby minimizing substrate reflection. Additionally, these compositions incorporate etching resistance enhancement silicon- or metal-containing units, to ensure effective image transfer from the photoresist to the substrate while minimizing resist leakage. In cases where the metal exhibits high EUV photo absorption, the resist underlayer composition also aids in dose reduction.

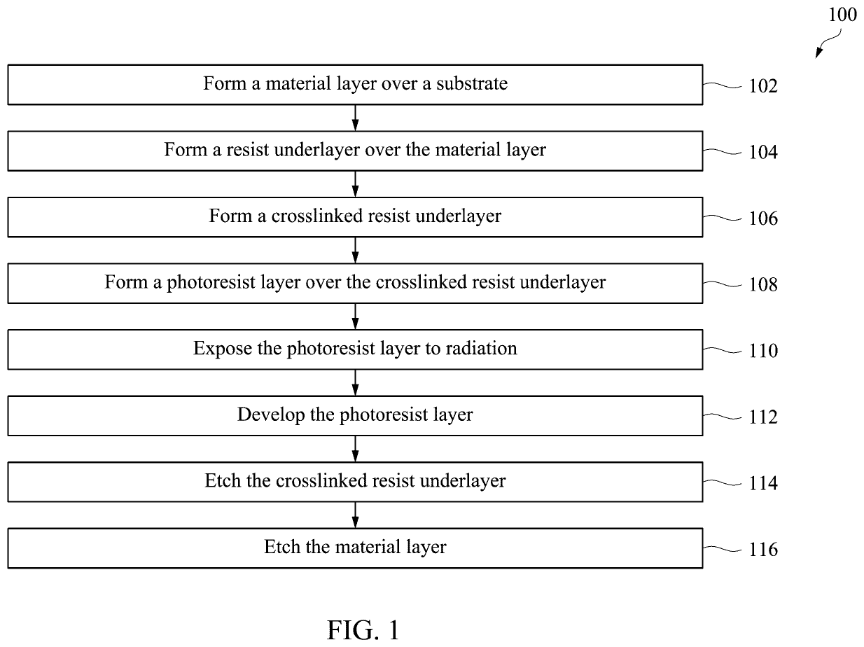

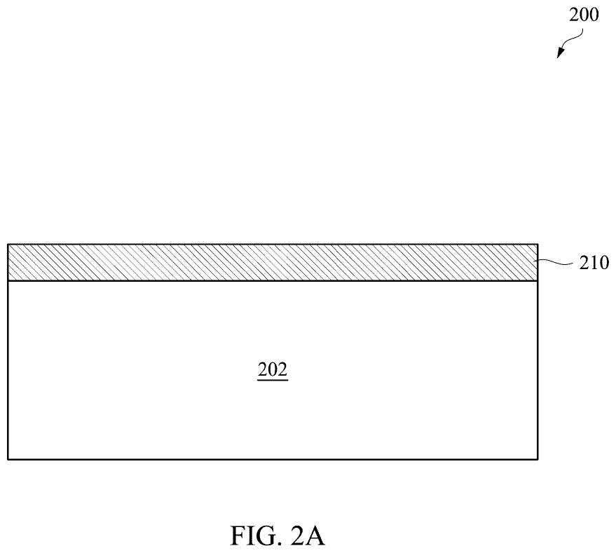

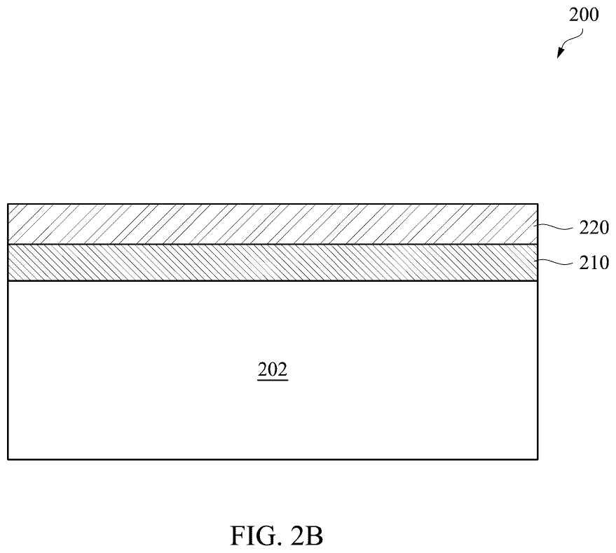

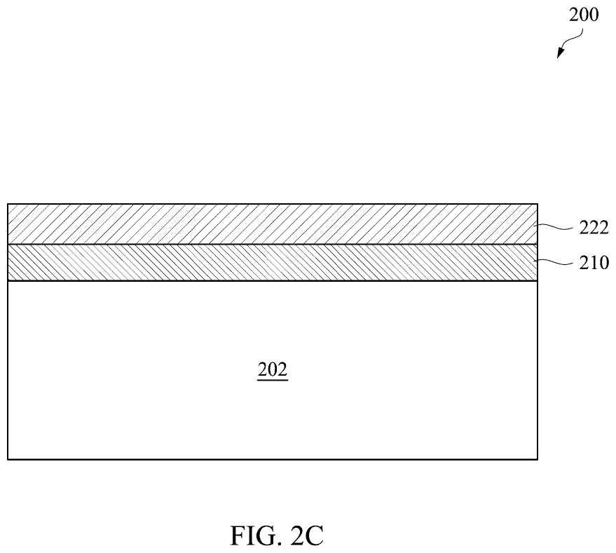

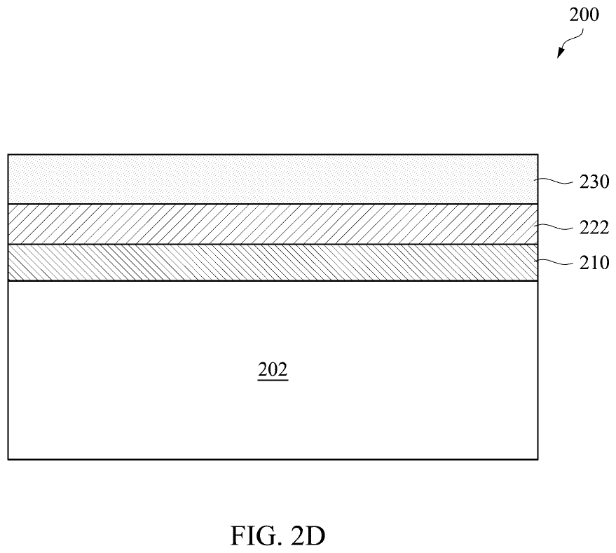

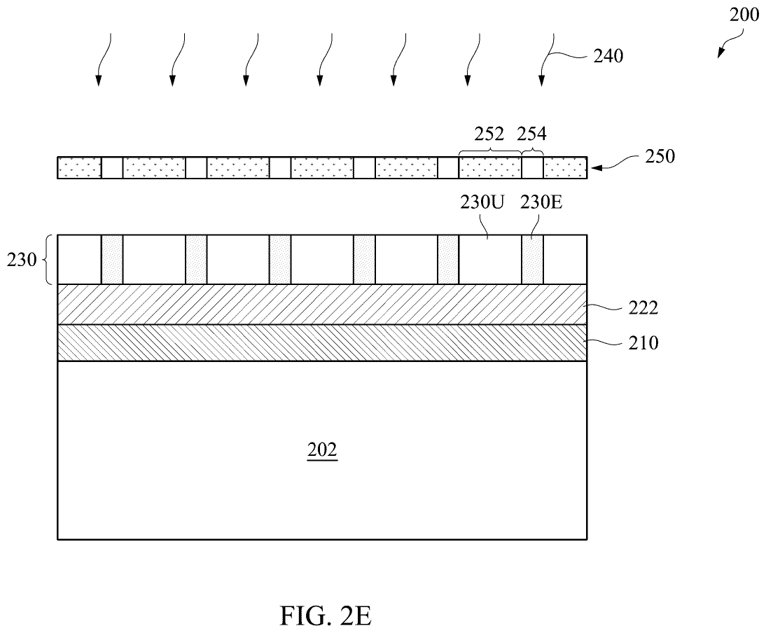

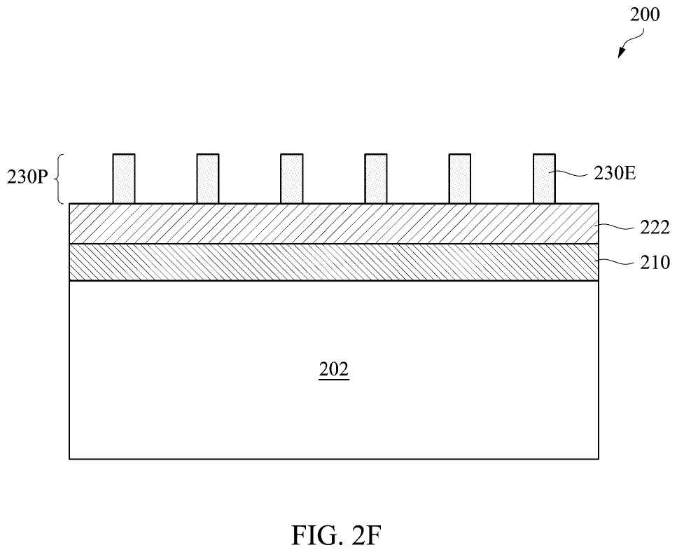

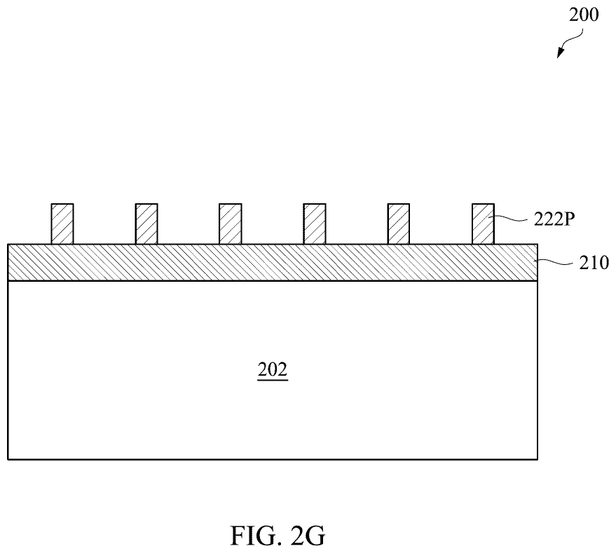

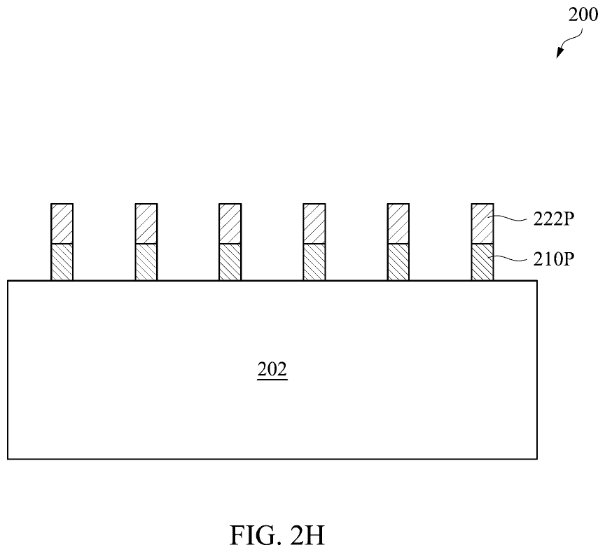

FIG. 1 is a flowchart of a method 100 of forming a semiconductor device, in accordance with some embodiments of the present disclosure. FIGS. 2A-2H are cross-sectional views of a semiconductor device 200 fabricated according to one or more steps of the method 100. It is understood that additional steps can be provided before, during, and after the method 100, and some of the steps described below can be replaced or eliminated, for additional embodiments of the method. It is further understood that additional features can be added in the semiconductor device 200, and some of the features described below can be replaced or eliminated, for additional embodiments of the semiconductor device 200.

The semiconductor device 200 may be an intermediate device fabricated during processing of an integrated circuit, or portion thereof, that may comprise static random access memory (SRAM) and/or other logic circuits, passive components such as resistors, capacitors, and inductors, and active components such as P-channel field effect transistors (PFET), N-channel FET (NFET), metal-oxide semiconductor field effect transistors (MOSFET), complementary metal-oxide semiconductor (CMOS) transistors, bipolar transistors, high voltage transistors, high frequency transistors, other memory cells, and combinations thereof. The semiconductor device 200 includes a plurality of semiconductor devices (e.g., transistors), which may be interconnected.

Referring to FIGS. 1 and 2A, the method 100 include an operation 102, in which a material layer 210 is deposited over a substrate 202, in accordance with some embodiments. FIG. 2A is a cross-sectional view of a semiconductor device 200 after depositing the material layer 210 over the substrate 202.

In some embodiments, the substrate 202 is a bulk semiconductor substrate including one or more semiconductor materials. In some embodiments, the substrate 202 includes silicon, silicon germanium, carbon doped silicon (Si: C), silicon germanium carbide, or other suitable semiconductor materials. In some embodiments, the substrate 202 is composed entirely of silicon.

In some embodiments, the substrate 202 includes one or more epitaxial layers formed on a top surface of a bulk semiconductor substrate. In some embodiments, the one or more epitaxial layers introduce strains in the substrate 202 for performance enhancement. For example, the epitaxial layer includes a semiconductor material different from that of the bulk semiconductor substrate, such as a layer of silicon germanium overlying bulk silicon or a layer of silicon overlying bulk silicon germanium. In some embodiments, the epitaxial layer(s) incorporated in the substrate 202 are formed by selective epitaxial growth, such as, for example, metalorganic vapor phase epitaxy (MOVPE), molecular beam epitaxy (MBE), hydride vapor phase epitaxy (HVPE), liquid phase epitaxy (LPE), metal-organic molecular beam epitaxy (MOMBE), or combinations thereof.

In some embodiments, the substrate 202 may be a semiconductor-on-insulator (SOI) substrate. In some embodiments, the SOI substrate includes a semiconductor layer, such as a silicon layer formed on an insulator layer. In some embodiments, the insulator layer is a buried oxide (BOX) layer including silicon oxide or silicon germanium oxide. The insulator layer is provided on a handle substrate such as, for example, a silicon substrate. In some embodiments, the SOI substrate is formed using separation by implanted oxygen (SIMOX) or other suitable techniques, such as wafer bonding and grinding.

In some embodiments, the substrate 202 may also include a dielectric substrate such as silicon oxide, silicon nitride, silicon oxynitride, a low-k dielectric, silicon carbide, and/or other suitable materials.

In some embodiments, the substrate 202 may also include various p-type doped regions and/or n-type doped regions, implemented by a process such as ion implantation and/or diffusion. Those doped regions include n-well, p-well, lightly doped region (LDD) and various channel doping profiles configured to form various IC devices, such as a CMOS transistor, imaging sensor, and/or light emitting diode (LED). The substrate 202 may further include other functional features such as a resistor and/or a capacitor formed in and/or on the substrate 202.

In some embodiments, the substrate 202 may also include various isolation features. The isolation features separate various device regions in the substrate 202. The isolation features include different structures formed by using different processing technologies. For example, the isolation features may include shallow trench isolation (STI) features. The formation of an STI may include etching a trench in the substrate 202 and filling in the trench with insulator materials such as silicon oxide, silicon nitride, and/or silicon oxynitride. The filled trench may have a multi-layer structure such as a thermal oxide liner layer with silicon nitride filling the trench. A chemical mechanical polishing (CMP) may be performed to polish back excessive insulator materials and planarize the top surface of the isolation features.

In some embodiments, the substrate 202 may also include gate stacks formed by dielectric layers and electrode layers. The dielectric layers may include an interfacial layer and a high-k dielectric layer deposited by suitable techniques, such as chemical vapor deposition (CVD), atomic layer deposition (ALD), physical vapor deposition (PVD), thermal oxidation, combinations thereof, and/or other suitable techniques. The interfacial layer may include silicon dioxide and the high-k dielectric layer may include LaO, AlO, ZrO, TiO, Ta₂O₅, Y₂O₃, SrTiO₃, BaTiO₃, BaZrO, HfZrO, HfLaO, HfSiO, LaSiO, AlSiO, HfTaO, HfTiO, (Ba,Sr)TiO₃ (BST), Al₂O₃, Si₃N₄, SiON, and/or other suitable materials. The electrode layer may include a single layer or alternatively a multi-layer structure, such as various combinations of a metal layer with a work function to enhance the device performance (work function metal layer), liner layer, wetting layer, adhesion layer and a conductive layer of metal, metal alloy or metal silicid). The electrode layer may include Ti, Ag, Al, TiAlN, TaC, TaCN, TaSiN, Mn, Zr, TiN, TaN, Ru, Mo, Al, WN, Cu, W, any suitable materials, and/or a combination thereof.

In some embodiments, the substrate 202 may also include a plurality of inter-level dielectric (ILD) layers and conductive features integrated to form an interconnect structure configured to couple the various p-type and n-type doped regions and the other functional features (such as gate electrodes), resulting in a functional integrated circuit. In one example, the substrate 202 may include a portion of the interconnect structure and the interconnect structure may include a multi-layer interconnect (MLI) structure and an ILD layer integrated with a MLI structure, providing an electrical routing to couple various devices in the substrate 202 to the input/output power and signals. The interconnect structure includes various metal lines, contacts and via features (or via plugs). The metal lines provide horizontal electrical routing. The contacts provide vertical connection between silicon substrate and metal lines while via features provide vertical connection between metal lines in different metal layers.

A material layer 210 is disposed on the substrate 202. The material layer 210 is configured to be patterned in subsequent manufacturing processes. The material layer 210 may be one or more material layers. In some embodiments, the material layer 210 is a semiconductor layer, a conductive layer such as a metallization layer, or a dielectric layer, such as a passivation layer, disposed over a metallization layer. In embodiments where the material layer 210 is a metallization layer, the material layer 210 may be formed of a conductive material using metallization processes, and metal deposition techniques, including CVD, ALD, and PVD. Likewise, if the material layer 210 is a dielectric layer, the material layer 210 may be formed by dielectric layer formation techniques, including thermal oxidation, CVD, ALD, and PVD

Referring to FIGS. 1 and 2B, the method 100 proceeds to operation 104, in which a resist underlayer 220 is deposited over the material layer 210, in accordance with some embodiments. FIG. 2B is a cross-sectional view of the semiconductor device 200 of FIG. 2A after depositing the resist underlayer 220 over the material layer 210.

The resist underlayer 220 includes a material composition that provides high etching selectivity relative to a photoresist layer formed thereon (e.g., photoresist layer 230 in FIG. 2D) and the underlying material layer 210. The resist underlayer 220 thus functions as an etch mask to transfer a pattern to the material layer 210. Additionally, the resist underlayer 220 serves as a bottom anti-reflective coating (BARC) layer, absorbing actinic radiation that passes through the photoresist layer. This prevents the actinic radiation from reflecting off the substrate 202 to expose unintended portions of the photoresist layer. Thus, the resist underlayer 220 helps to improve line width roughness and line edge roughness of the photoresist pattern formed by EUV lithography.

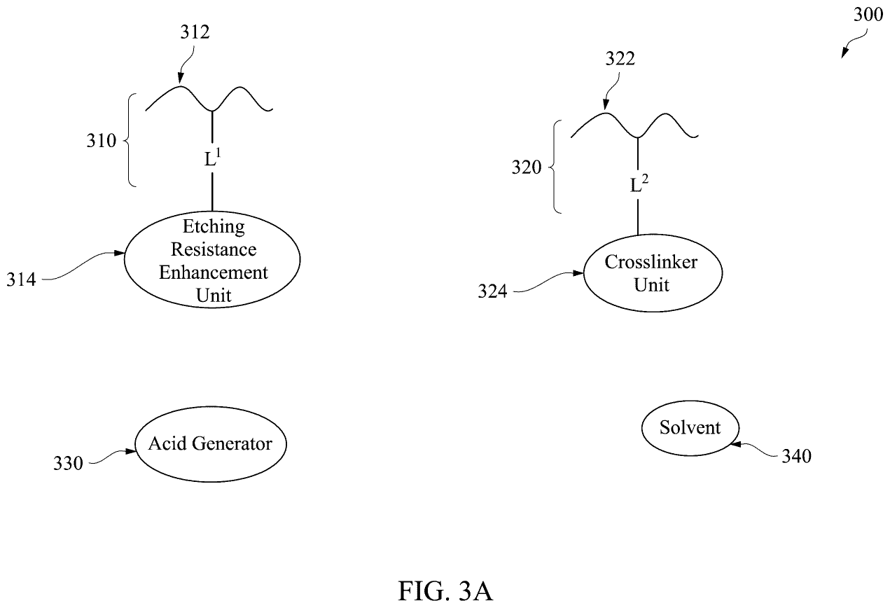

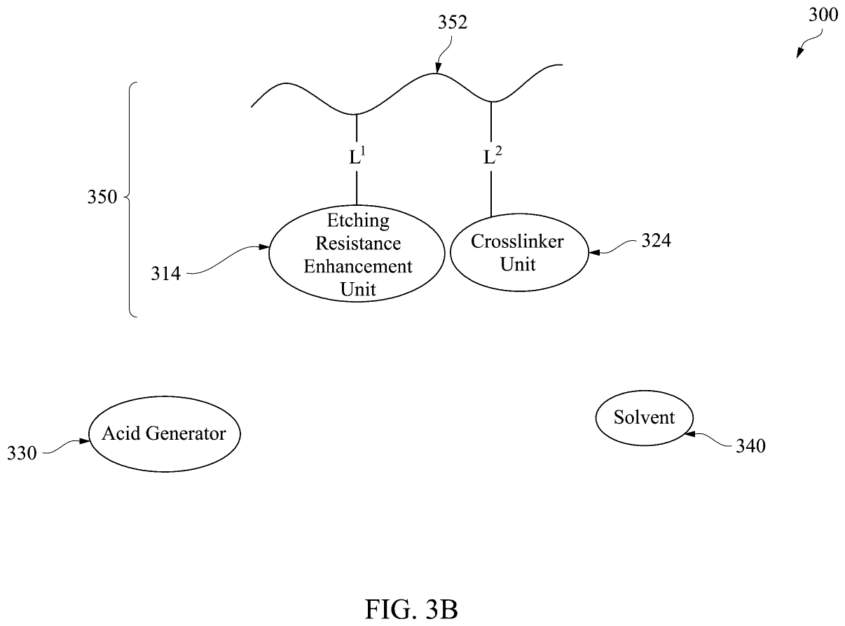

FIG. 3A shows an embodiment of a resist underlayer composition 300, in portion, included in the resist underlayer 220, in accordance with some embodiments of the present disclosure. The resist underlayer composition 300 includes a first polymer 310 including a functional unit capable of enhancing etching resistance of the resist underlayer 220, a second polymer 320 including a reactive unit capable of increasing the solvent resistance of the resist underlayer 220, an acid generator 330, and a solvent 340.

In some embodiments, the first polymer 310 includes a polymer backbone 312 and an etching resistance enhancement unit 314 covalently bonded to the polymer backbone 312 via linker L¹. In some embodiments, the etching resistance enhancement unit 314 is present in the first polymer 310 in an amount ranging from about 1 wt. % to about 50 wt. % of the first polymer. If the amount of the etching resistance enhancement unit is less than about 1 wt. %, the resist underlayer 220 may not have sufficient etching selectivity relative to the photoresist layer and the underlying material layer. If the amount of the etching resistance enhancement unit is greater than about 50 wt. %, the first polymer 310 may lack sufficient solubility in the solvent.

In some embodiments, the first polymer 310 has the following structure (I):

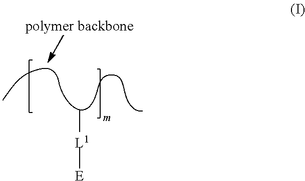

wherein:
L¹ is, at each occurrence, independently an alkylene, alkenylene, alkynylene, heteroalkylene, heteroalkenylene, heteroalkynylene, cycloalkylene, heterocycloalkylene, arylene, heteroarylene or heteroatomic linker;
E is, at each occurrence, an etching resistance enhancing unit; and
n is an integer of one or greater.

In some embodiments, the polymer backbone 312 has a hydrocarbon structure. In some embodiments, the first polymer 310 is a polyhydroxy styrene, polyacrylate, or polymethacrylate-based polymer. In some embodiments, the first polymer 310 includes a backbone derived from one or more of monomers such as, for example, methyl acrylate, ethyl acrylate, n-propyl acrylate, isopropyl acrylate, n-butyl acrylate, isobutyl acrylate, tert-butyl acrylate, n-hexyl acrylate, 2-ethylhexyl acrylate, acetoxyethyl acrylate, phenyl acrylate, 2-hydroxyethyl acrylate, 2-methoxyethyl acrylate, 2-ethoxyethyl acrylate, 2-(2-methoxyethoxy)ethyl acrylate, cyclohexyl acrylate, benzyl acrylate, 2-alkyl-2-adamantyl (meth)acrylate or dialkyl(1-adamantyl)methyl (meth)acrylate, methyl methacrylate, ethyl methacrylate, n-propyl methacrylate, isopropyl methacrylate, n-butyl methacrylate, isobutyl methacrylate, tert-butyl methacrylate, n-hexyl methacrylate, 2-ethylhexyl methacrylate, acetoxyethyl methacrylate, phenyl methacrylate, 2-hydroxyethyl methacrylate, 2-methoxyethyl methacrylate, 2-ethoxyethyl methacrylate, 2-(2-methoxyethoxy)ethyl methacrylate, cyclohexyl methacrylate, benzyl methacrylate, 3-chloro-2-hydroxypropyl methacrylate, 3-acetoxy-2-hydroxypropyl methacrylate, 3-chloroacetoxy-2-hydroxypropyl methacrylate, or hydroxy styrene.

The etching resistance enhancement unit 314 is a silicon- or a metal-containing unit for enhancing the etching resistance of the resist underlayer 220. In some embodiments, the silicon- or metal-containing unit is a low-etching unit having a high EUV absorption coefficient. Upon exposure to EUV, this unit generates secondary electrons, which can react with the metal-carbon bond in the metallic photoresist to stabilize the metallic photoresist intermediates. Consequently, the silicon- or metal-containing unit helps to enhance the crosslinking of the metallic photoresist and achieve dose reduction. The silicon- or metal-containing unit may be an organic or inorganic cage, nanoparticle, monomer, oligomer, or polymer.

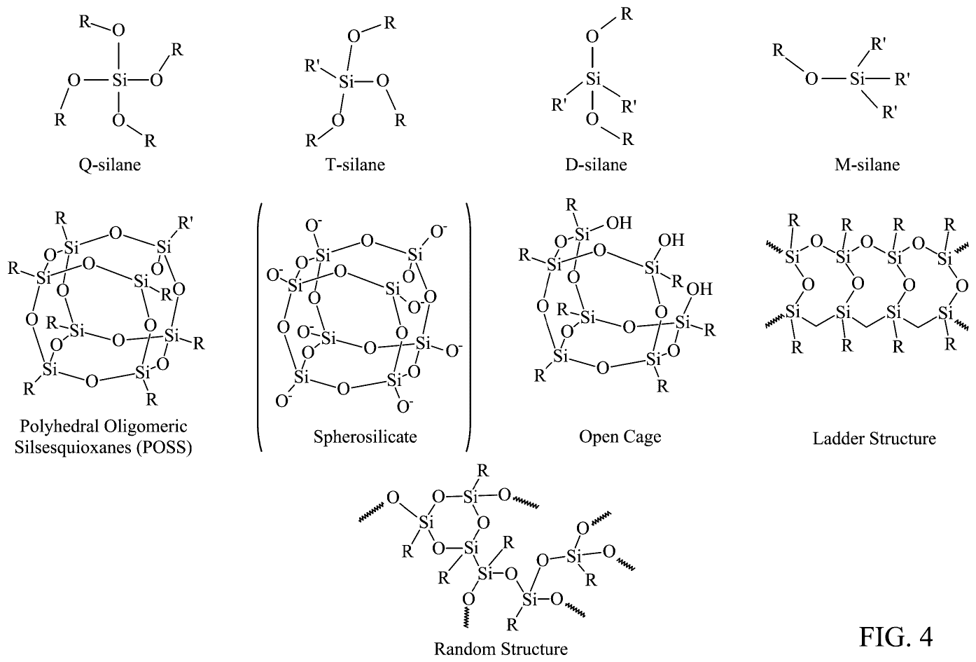

In some embodiments, the etching resistance enhancement unit 314 is a silicon-containing unit including silicon-oxygen bonds. In some embodiments, the silicon-containing unit may be derived from a silane. Examples of silanes including Q-silane, T-silane, D-silane, and M-silane are illustrated in FIG. 4. In some embodiments, the silicon-containing unit may be derived from a silsesquioxane. The silsesquioxane may be a cage type silsesquioxane, an open cage type silsesquioxane, a ladder type silsequioxane, or a random type silsesquioxane. Examples of silsesquioxanes are illustrated in FIG. 4. In FIG. 4, R and R′ are, at each occurrence, independently cyclic or noncyclic, saturated or unsaturated, substituted or unsubstituted, or branched or unbranched C1-C12 aliphatic groups including C1-C12 alkyl or C2-C12 alkenyl groups. The C1-C12 alkyl groups or C2-C12 alkenyl groups may be substituted with one or more substituents selected from halogen, —SH, —PH₃, —PO₂, —C(═O)SH, —C(═O)OH, —OH, —NH₂, —C(═O)NH₂, —SO₂OH, —SO₂SH, —SOH, —SO₂, ether, ketone, ester, epoxy, and aryl such as phenyl.

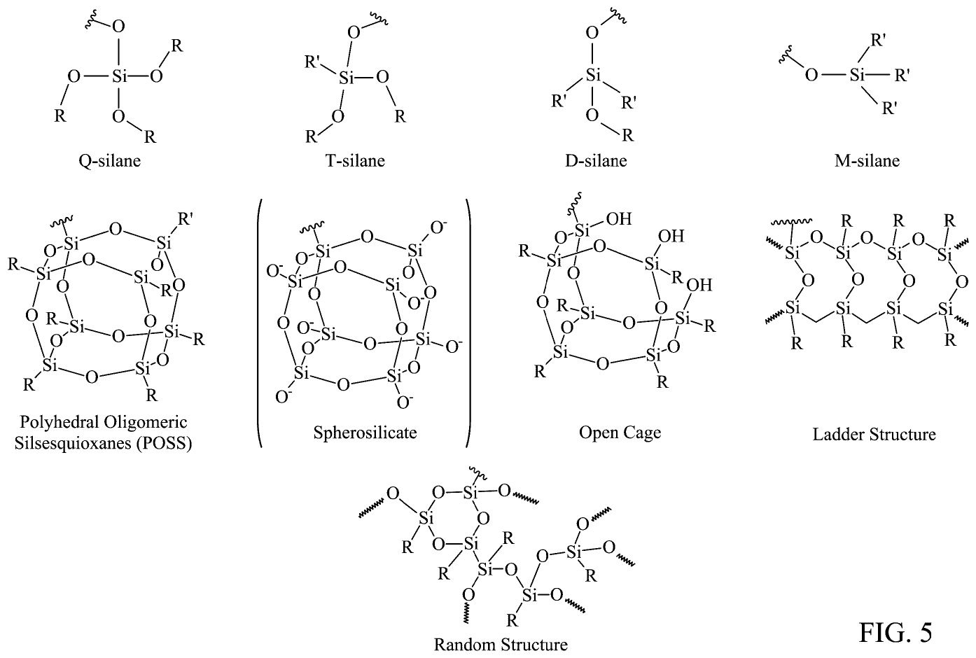

The silicon-containing unit derived from silane or silsesquioxane may have a monovalent or divalent structure. The monovalent structure may be formed by losing one R group or one R′ group from a corresponding silane or silsesquioxane. The bivalent structure may be formed by losing two R groups, two R′ groups, or one R group and one R′ group from a corresponding silane or silsesquioxane. Examples of monovalent silicon-containing units are illustrated in FIG. 5. The symbol “ [symbol] ” represents the bond to the linker L¹.

In some embodiments, the etching resistance enhancement unit 314 is a metal-containing unit including metal-oxygen bonds. In some embodiments, the metal has a high EUV absorption coefficient. Examples of metals include, but are not limited to, aluminum (Al), cadmium (Cd), chromium (Cr), cobalt (Co), copper (Cu), hafnium (Hf), indium (In), iron (Fe), manganese (Mn), molybdenum (Mo), nickel (Ni), niobium (Nb), scandium (Sc), silver (Ag), tantalum (Ta), titanium (Ti), tin (Sn), tungsten (W), vanadium (V), zinc (Zn), zirconium (Zr), and combinations thereof. In some embodiments, the metal in the metal-containing unit is Sn, Hf, Zn, Ti, Zr, W, or Sc. In some embodiments, the metal-containing unit is derived from an organometallic compound having the following structure:

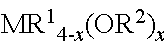

wherein:
M is a metal;
R¹ and R² are independently C1-C12 alkyl; and
x is an integer from 0 to 4.

In some embodiments, M is Sn, Hf, Zn, Ti Zr, W or Sc.

In some embodiments, the organometallic compound is an organotin compound selected from SnR¹₃(OR²)₁, SnR¹₂(OR²)₂, SnR¹₁(OR²)₃, and SnR²₄.

In some embodiments, the organometallic compound is an organohafnium compound selected from HfR¹₃(OR²)₁, HfR¹₂(OR²)₂, HfR¹₁(OR²)₃, and HfR²₄.

In some embodiments, the organometallic compound is an organozinc compound selected from ZnR¹₃(OR²)₁, ZnR¹₂(OR²)₂, ZnR¹₁(OR²)₃, and ZnR²₄.

In some embodiments, R¹ and R² are each —CH₃.

In some embodiments, the metal-containing unit derived from such organometallic compound may include Sn₁₂Ox, Hf₄Oₓ, or Zn₄Oₓ.

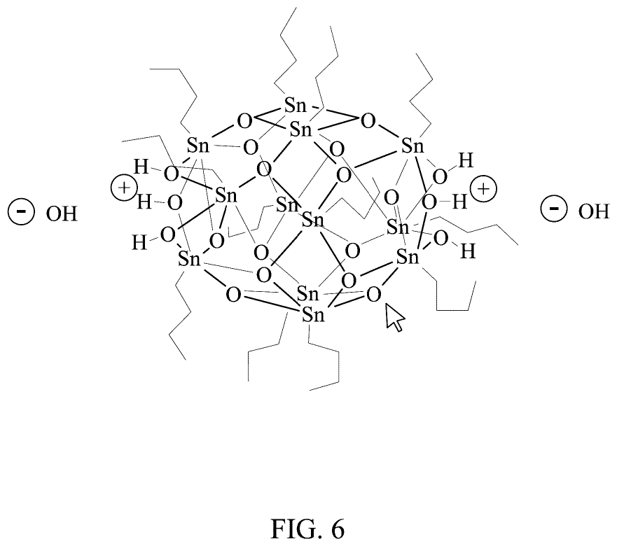

In some embodiments, the metal-containing unit may be derived from an organotin dodecamer cluster as shown in FIG. 6.

The metal-containing unit derived from the above organometallic compound may have a monovalent or divalent structure. The monovalent structure may be formed from the above organometallic compound by losing one R¹ group or one R² group therein. The bivalent structure may be formed from the above organometallic compound by losing two R¹ groups, two R² groups, or one R¹ group and one R² group. In some embodiments, the monovalent metal-containing unit has the following structure:

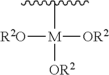

wherein [symbol] represents the bond to the linker L¹.

In some embodiments, the metal-containing unit is derived from a metal oxide having the following structure:

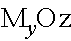

wherein:
M is a metal;
y and z are integers of one or greater.

In some embodiments, M is Sn, W, Zn, Sc, Fe, Ti or V.

In some embodiments, y and z each an integer from 1 to 6.

In some embodiments, the metal oxide comprises SnO₂, WO₃, ZnO, ZnO₂, Sc₂O₃, Fe₂O₃, FeO₂, Al₂O₃, TiO, TiO₂, or V₂O₅.

The linker L¹ is, at each occurrence, independently a substituted and unsubstituted, branched and unbranched divalent aliphatic group, a substituted and unsubstituted divalent aromatic group, a unsubstituted or halogen-substituted divalent C3-C9 carbocyclic group, —S—, —P—, —P(O₂)—, —C(═O)S—, —C(═O)O—, —O—, —N—, —C(═O)N—, —SO₂O—, —SO₂S—, —SO—, —SO₂— or combinations thereof.

In some embodiments, L¹ comprises C₁-C₁₂ alkylene or C₁-C₁₂ alkylene covalently bonded to —S—, —P—, —P(O₂)—, —C(═O)S—, —C(═O)O—, —O—, —N—, —C(═O)NH—, —SO₂O—, —SO₂S—, —SO—, —SO₂—, —C₆H₆—O—, —C₆H₆—O—C(═O)O—, or —C(═O)—.

In some embodiments, L¹ is —C(═O)O—. In some embodiments, L¹ is —C(═O)O—(CH₂)₁₋₆—. In some embodiments, L¹ is

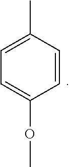

In some embodiments, m is an integer from 1 to 300, for example, from 1 to 100, from 1 to 50, from 1 to 25, or from 1 to 10. In certain embodiments, m is 1, 2, 3, 4, 5, 6, 7, 8, 9, 10, 11, 12, 13, 14, 15, 16, 17, 18, 19, 20, 21, 22, 23, 24, or 25.

In some embodiments, the first polymer 310 has one of the following structures:

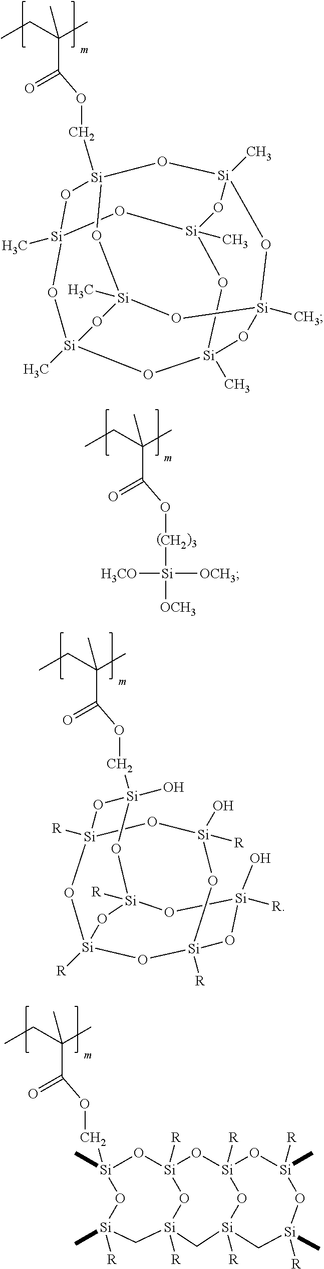

In some embodiments, the second polymer 320 includes a polymer backbone 322 and a crosslinker unit 324 covalently bonded to the polymer backbone 322 via linker L². In some embodiments, the crosslinker unit 324 is present in the second polymer 320 in an amount ranging from about 5 wt. % to about 70 wt. % of the second polymer 320. If the amount of the crosslinker unit is less than about 5 wt. %, the resist underlayer may have insufficient solvent resistance to the photoresist developer. If the amount of the crosslinker unit is greater than about 70 wt. %, the second polymer may lack sufficient solubility in the solvent.

In some embodiments, the second polymer 320 has the following structure (II):

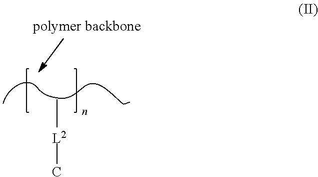

wherein:
L² is, at each occurrence, independently an alkylene, alkenylene, alkynylene, heteroalkylene, heteroalkenylene, heteroalkynylene, cycloalkylene, heterocycloalkylene, arylene, heteroarylene or heteroatomic linker;
C is, at each occurrence, a crosslinker unit comprising one or more crosslinkable groups; and
n is an integer of one or greater.

In some embodiments, the polymer backbone 322 has a hydrocarbon structure. In some embodiments, the second polymer 320 is a polyhydroxy styrene, polyacrylate, or polymethacrylate-based polymer. In some embodiments, the second polymer 320 includes a backbone derived from one or more of monomers such as, for example, methyl acrylate, ethyl acrylate, n-propyl acrylate, isopropyl acrylate, n-butyl acrylate, isobutyl acrylate, tert-butyl acrylate, n-hexyl acrylate, 2-ethylhexyl acrylate, acetoxyethyl acrylate, phenyl acrylate, 2-hydroxyethyl acrylate, 2-methoxyethyl acrylate, 2-ethoxyethyl acrylate, 2-(2-methoxyethoxy)ethyl acrylate, cyclohexyl acrylate, benzyl acrylate, 2-alkyl-2-adamantyl(meth)acrylate or dialkyl (1-adamantyl)methyl (meth)acrylate, methyl methacrylate, ethyl methacrylate, n-propyl methacrylate, isopropyl methacrylate, n-butyl methacrylate, isobutyl methacrylate, tert-butyl methacrylate, n-hexyl methacrylate, 2-ethylhexyl methacrylate, acetoxyethyl methacrylate, phenyl methacrylate, 2-hydroxyethyl methacrylate, 2-methoxyethyl methacrylate, 2-ethoxyethyl methacrylate, 2-(2-methoxyethoxy)ethyl methacrylate, cyclohexyl methacrylate, benzyl methacrylate, 3-chloro-2-hydroxypropyl methacrylate, 3-acetoxy-2-hydroxypropyl methacrylate, 3-chloroacetoxy-2-hydroxypropyl methacrylate, or hydroxy styrene. In some embodiments, the second polymer 320 may have a polymer backbone 322 the same as the polymer backbone 312 of the first polymer 310. In some embodiments, the second polymer 320 may have a polymer backbone 322 different from the polymer backbone 312 of the first polymer 310.

The crosslinker unit 324 may be any suitable crosslinker. The crosslinker unit 324 on one of polymer chains is operable to react with another crosslinker unit 324 on another one of polymer chains under heat. The reaction of the crosslinker unit 324 bonds two polymer chains together to form polymer networks. The crosslinking improves the solvent resistance of the resist underlayer 220, so that the resist underlayer 220 will not be dissolved by the solvent used to form the photoresist layer. The crosslinking also increases the molecular weight of the polymer resin in the resist underlayer 220, which results in increased glass transition temperature and overall density in the resist underlayer 220. In some embodiments, the crosslinker unit 324 is an aliphatic or aromatic group comprising one or more crosslinkable groups selected from epoxy, hydroxide, azo, alkyl halide, imine, alkene, alkyne, peroxide, ketone, aldehyde, allene, silane, or heterocyclic groups.

In some embodiments, the crosslinker unit 324 has one of the following structures:

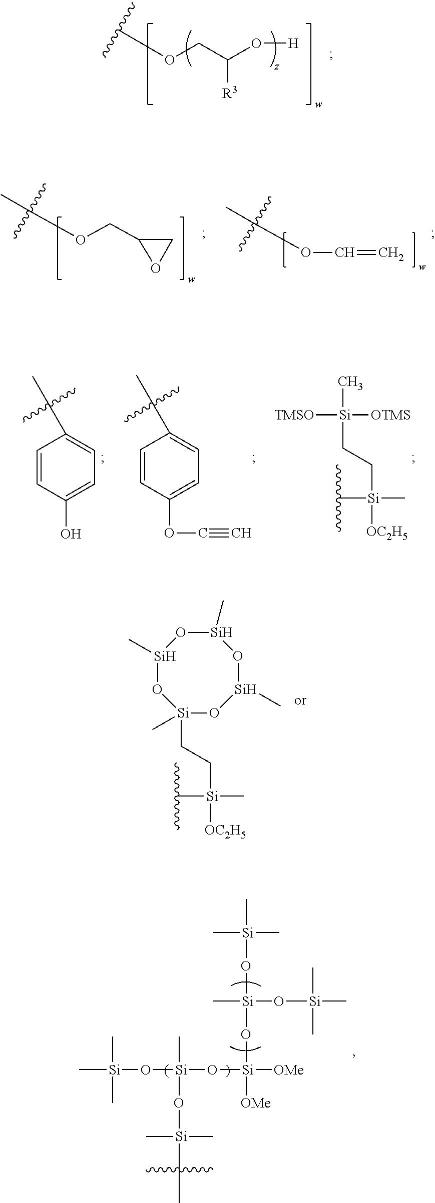

wherein:
R³ is, at each occurrence, H, alkyl, heteroalkyl, aryl, or heteroaryl;
z is an integer of 1 to 300; and
w is an integer of 1 to 6.

In some embodiments, R³ is a cyclic or noncyclic, saturated or unsaturated, substituted or unsubstituted, or branched or unbranched C₁-C₁₂ aliphatic or aromatic group. In some embodiments, R³ is an unsubstituted or halogen-substituted C₁-C₁₂ alkyl group. In some embodiments, R³ is a C1-C12 alkyl or C2-C12 alkenyl group substituted with one or more substituents selected from halogen, —SH, —PH₃, —PO₂, —C(═O)SH, —(═O)OH, —OH, —NH₂, —C(═O)NH₂, —SO₂OH, —SO₂OH, —SOH, —SO₂, ether, ketone, ester, epoxy, and aryl such as phenyl.

The linker L² is, at each occurrence, independently a substituted and unsubstituted, branched and unbranched divalent aliphatic group, a substituted and unsubstituted divalent aromatic group, a unsubstituted or halogen-substituted divalent C3-C9 carbocyclic group, —S—, —P—, —P(O₂)—, —C(═O)S—, —C(═O)O—, —O—, —N—, —C(═O)NH—, —SO₂O—, —SO₂S—, —SO—, —SO₂— or combinations thereof.

In some embodiments, L² comprises C₁-C₁₂ alkylene or C₁-C₁₂ alkylene covalently bonded to —S—, —P—, —P(O₂)—, —C(═O)S—, —C(═O)O—, —O—, —N—, —C(═O)NH—, —SO₂O—, —SO₂S—, —SO—, —SO₂—, —C₆H₆—O—, —C₆H₆—O—C(═O)O—, or —C(═O)—.

In some embodiments, L² is —C(═O)O—. In some embodiments, L² is —C(═O)O—(CH₂)₁₋₆—. In some embodiments, L² is

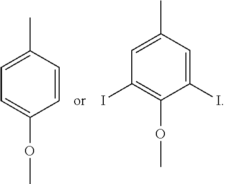

In some embodiments, n is an integer from 1 to 300, for example, from 1 to 100, from 1 to 50, from 1 to 25, or from 1 to 10. In certain embodiments, n is 1, 2, 3, 4, 5, 6, 7, 8, 9, 10, 11, 12, 13, 14, 15, 16, 17, 18, 19, 20, 21, 22, 23, 24, or 25.

In some embodiments, the second polymer 320 has one of the following structures:

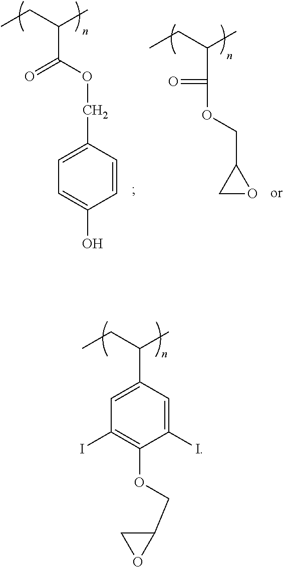

In some embodiments, the etching resistance enhancement unit 314 and crosslinker unit 324 are attached to the same polymer backbone. FIG. 3B shows another embodiment of a resist underlayer composition 300, in portion, included in the resist underlayer 220, in accordance with some embodiments of the present disclosure. Unlike the embodiment illustrated in FIG. 3A, in which the polymer resin in the resists underlayer composition 300 includes a mixture of two homopolymers, i.e., first polymer 310 and second polymer 320, the resist underlayer composition 300 illustrated in FIG. 3B includes a copolymer 350. In some embodiments, the copolymer 350 includes a polymer backbone 352, an etching resistance enhancement unit 314 attached the polymer backbone 352 via linker L¹, and a crosslinker unit 324 attached to the polymer backbone 352 via linker L².

In some embodiments, the copolymer 350 having the following structure (III):

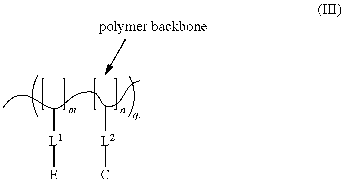

wherein:
L¹ and L² are, at each occurrence, independently alkylene, alkenylene, alkynylene, heteroalkylene, heteroalkenylene, heteroalkynylene, cycloalkylene, heterocycloalkylene, arylene, heteroarylene or heteroatomic linkers,
E is, at each occurrence, independently an etching resistance enhancement unit;
C is, at each occurrence, independently a crosslinker unit comprising one or more crosslinkable groups; and
m, n and q are independently an integer of one or greater.

In the polymer of structure (III), the polymer backbone, the linkers L¹ and L², the etching resistance enhancement unit (E), and the crosslinker unit (C) are as previously described for the first polymer 310 and the second polymer 320.

In some embodiments, m is an integer from 1 to 300, for example, from 1 to 100, from 1 to 50, from 1 to 25, or from 1 to 10. In certain embodiments, m is 1, 2, 3, 4, 5, 6, 7, 8, 9, 10, 11, 12, 13, 14, 15, 16, 17, 18, 19, 20, 21, 22, 23, 24, or 25.

In some embodiments, n is an integer from 1 to 300, for example, from 1 to 100, from 1 to 50, from 1 to 25, or from 1 to 10. In certain embodiments, n is 1, 2, 3, 4, 5, 6, 7, 8, 9, 10, 11, 12, 13, 14, 15, 16, 17, 18, 19, 20, 21, 22, 23, 24, or 25.

In some embodiments, q is, at each occurrence, independently an integer from 1 to 100, for example, from 1 to 50, from 1 to 25, or from 1 to 10. In certain embodiments, q is 1, 2, 3, 4, 5, 6, 7, 8, 9, 10, 11, 12, 13, 14, 15, 16, 17, 18, 19, 20, 21, 22, 23, 24, or 25.

In some embodiments, the copolymer 350 has one of the following structures:

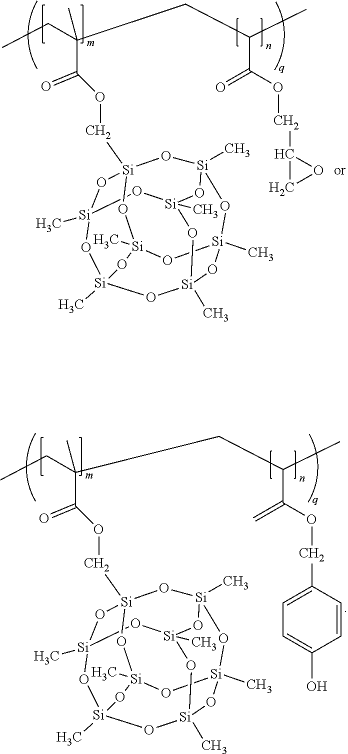

In some embodiments, the resist underlayer composition 300 further includes an acid generator 330 for triggering the crosslinking reaction of the crosslinker unit 324. In some embodiments, the acid generator 330 includes a thermal acid generator (TAG), a photoacid generator (PAG), or a combination thereof.

In some embodiments, the acid generator 330 includes a thermal generator that generates an acid upon heating. In some embodiments, the thermal acid generator is selected from the group consisting of:

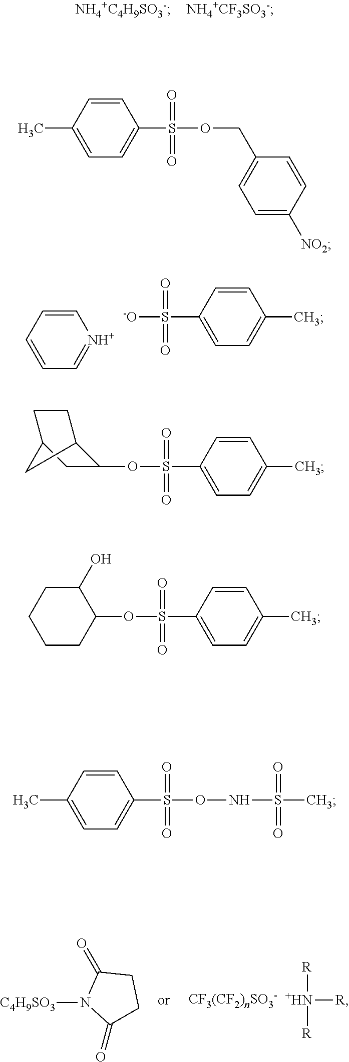

wherein:
R is H, alkyl, heteroalkyl, cycloalkyl, heterocycloalkyl, aryl or heteroaryl; and
n is an integer of 1 to 4.

In some embodiments, R is a cyclic or noncyclic, saturated or unsaturated, substituted or unsubstituted, or branched or unbranched C₁-C₁₂ aliphatic or aromatic group. In some embodiments, R is a unsubstituted or halogen-substituted C₁-C₁₂ alkyl group. In some embodiments, R is a C₁-C₁₂ alkyl or C₂-C₁₂ alkenyl group substituted with one or more substituents selected from halogen, —SH, —PH₃, —PO₂, —C(═O)SH, —C(═O)OH, —OH, —NH₂, —C(═O)NH₂, —SO₂OH, —SO₂SH, —SOH, —SO₂, ether, ketone, ester, epoxy, and aryl such as phenyl.

In some embodiments, the acid generator 330 includes a photoacid generator (PAG) that generates an acid when exposing to radiation, for example, EUV radiation or E-beam radiation.

In some embodiments, the photoacid generator may include a combination of a cation and an anion. Examples of photoacid generators according to embodiments of the disclosure include α-(trifluoromethylsulfonyloxy)-bicyclo[2.2.1]hept-5-ene-2,3-dicarb-o-ximide (MDT), N-hydroxy-naphthalimide (DDSN), benzoin tosylate, t-butylphenyl-α-(p-toluenesulfonyloxy) acetate and t-butyl-α-(p-toluenesulfonyloxy) acetate, triarylsulfonium and diaryliodonium hexafluoroantimonates, hexafluoroarsenates, trifluoromethanesulfonates, iodonium perfluorooctanesulfonate, N-camphorsulfonyloxynaphthalimide, N-pentafluorophenylsulfonyloxynaphthalimide, ionic iodonium sulfonates such as diaryl iodonium (alkyl or aryl) sulfonate and bis-(di-t-butylphenyl) iodonium camphanylsulfonate, perfluoroalkanesulfonates such as perfluoropentanesulfonate, perfluorooctanesulfonate, perfluoromethanesulfonate, aryl (e.g., phenyl or benzyl) triflates such as triphenylsulfonium triflate or bis(t-butylphenyl) iodonium triflate; pyrogallol derivatives (e.g., trimesylate of pyrogallol), trifluoromethanesulfonate esters of hydroxyimides, α,α′-bis-sulfonyl-diazomethanes, sulfonate esters of nitro-substituted benzyl alcohols, naphthoquinone-4-diazides, alkyl disulfones, or the like.

In some embodiments, the cation is selected from the group consisting of:

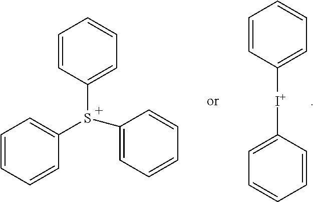

In some embodiments, the anion is selected from the group consisting of:

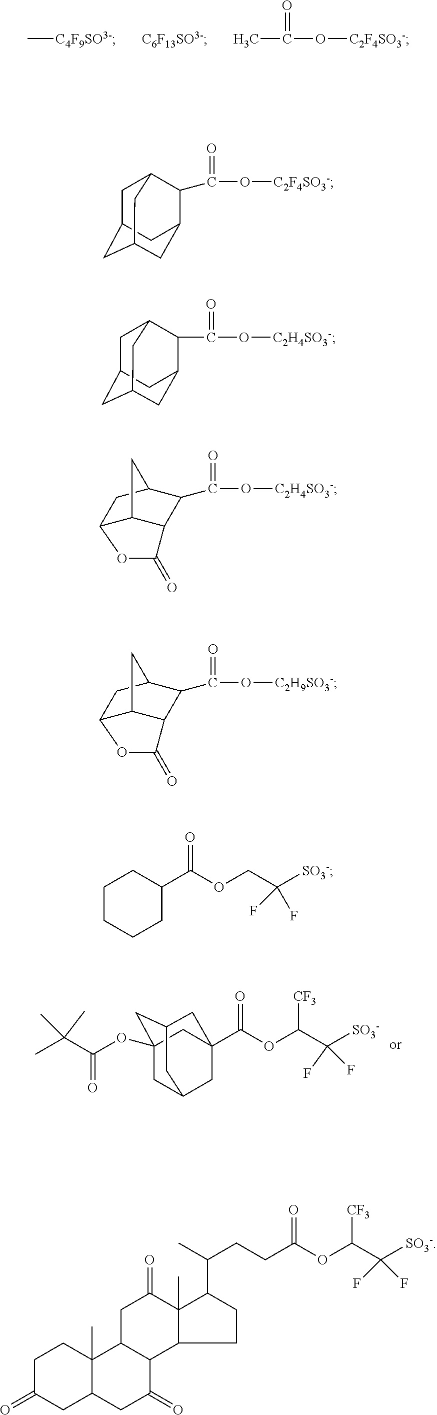

In some embodiments, the concentration of the acid generator 330 ranges from about 0.5 wt. % to about 30 wt. % based on the total weight of the resist underlayer composition.

At concentrations of the acid generator 330 below the disclosed ranges, there may not be enough acid generated to promote the crosslinking reaction of the crosslinker unit 324. At concentrations of the acid generator 330 greater than the disclosed ranges, there may not be a significant improvement in the efficiency of the crosslinking reaction of the crosslinker unit 324.

The resist underlayer composition 300 includes a solvent 340 in some embodiments. The solvent 340 can be any suitable solvent. In some embodiments, the solvent 340 is one or more selected from propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (mibc), n-butyl acetate (nBA), and 2-heptanone (MAK).

In some embodiments, the mixture of first polymer 310 and second polymer 320 or copolymer 350 and the acid generator 330 are added to the solvent 340 for application, and the resist underlayer 220 is formed by applying the resist underlayer composition onto the top surface of the material layer 210 if present, or onto the substrate 202, for example, by spin coating or imprint. Alternatively, the resist underlayer 220 may be formed by a suitable deposition process, such as, for example, CVD, PVD or ALD. In some embodiments, the resist underlayer 220 may be formed to have a thickness ranging from about 5 Å to about 500 Å. Layer thicknesses less than the disclosed ranges may be insufficient to provide adequate etching resistance and anti-reflective properties. Layer thicknesses greater than the disclosed ranges may not provide further improvement in etching resistance and anti-reflective properties but may result in a waste of materials.

Referring to FIGS. 1 and 2C, the method 100 proceeds to operation 106, in which a first baking process is performed, thereby forming a crosslinked resist underlayer 222, in accordance with some embodiments. FIG. 2C is a cross-sectional view of the semiconductor device 200 after performing the first baking process, in accordance with some embodiments.

The first baking process is performed at a temperature for a period of time that is sufficient to cause the crosslinker units 324 to react with each other and to bond the individual polymer chains of the second polymer 320, or individual polymer chains of the copolymer 350 in the resist underlayer 220 into polymer networks. In some embodiments, the first baking process is performed at a temperature ranging from about 100° C. to about 400° C. In certain embodiments, the first baking process is performed at a temperature of about 80° C. to about 200° C. for about 20 seconds to about 3 minutes. In other embodiments, the first baking process is performed at a temperature of about 100° C. to about 250° C. for about 10 seconds to about 2 minutes. The first baking process forms a crosslinked resist underlayer 222 with a good solvent resistance to allow application of the photoresist layer without dissolving the crosslinked resist underlayer 222.

Referring to FIGS. 1 and 2D, the method 100 proceeds to operation 108, in which a photoresist layer 230 is deposited over the crosslinked resist underlayer 222, in accordance with some embodiments. FIG. 2D is a cross-sectional view of the semiconductor device 200 of FIG. 2C after depositing the photoresist layer 230 over the crosslinked resist underlayer 222.

The photoresist layer 230 is a photosensitive layer that is patternable by exposure to radiation. Typically, the chemical properties of the photoresist regions struck by incident radiation change in a manner that depends on the type of photoresist used. The photoresist layer 230 includes either a positive tone resist or a negative tone resist. A positive tone resist refers to a photoresist material that when exposed to radiation, such as UV light, becomes soluble in a developer, while the region of the photoresist that is non-exposed (or exposed less) is insoluble in the developer. A negative tone resist, on the other hand, refers to a photoresist material that when exposed to radiation becomes insoluble in the developer, while the region of the photoresist that is non-exposed (or exposed less) is soluble in the developer. The region of a negative resist that becomes insoluble upon exposure to radiation may become insoluble due to a cross-linking reaction caused by the exposure to radiation.

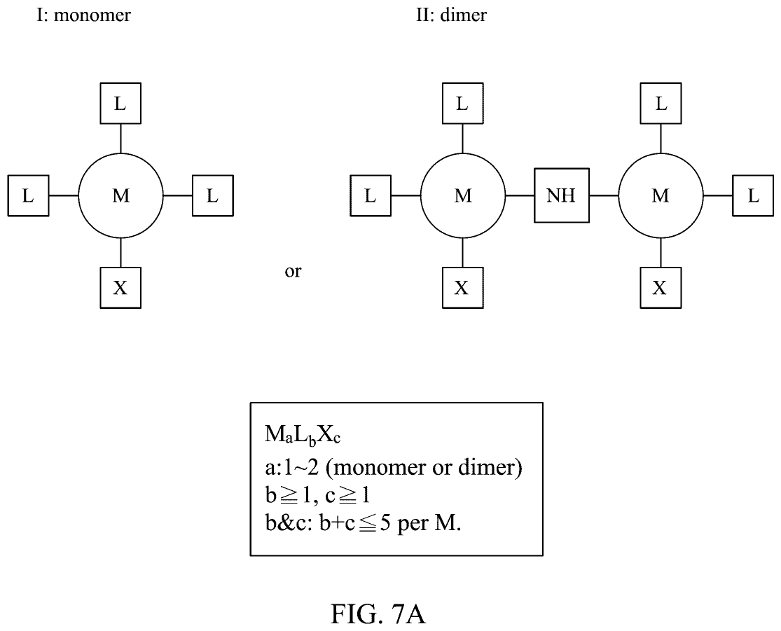

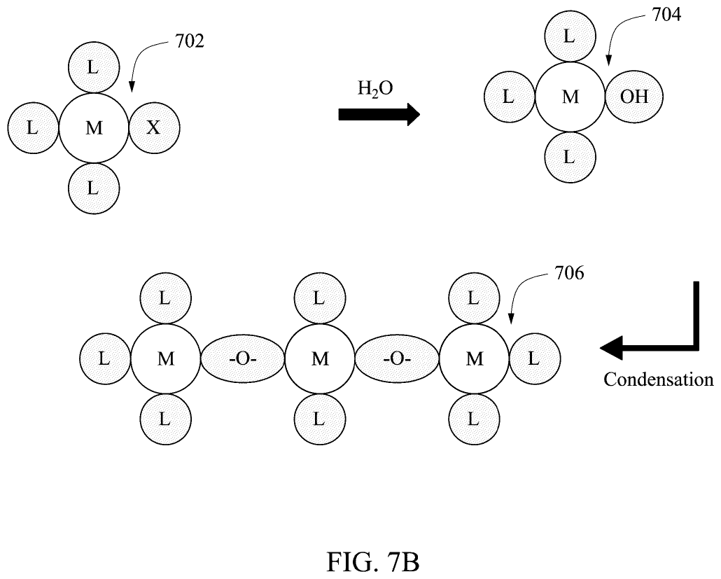

In some embodiments, the photoresist layer 230 includes a high sensitivity photoresist composition. In some embodiments, the high sensitivity photoresist composition includes a metal that has a high absorption coefficient for EUV radiation. In some embodiments, the photoresist layer 230 may include an organometallic compound containing a metal core coordinated with multiple organic ligands. In some embodiments and as shown in FIG. 7A, the organometallic compound has the following formula:

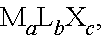

wherein:
M is at least one of tin (Sn), bismuth (Bi), antimony (Sb), indium (In), tellurium (Te), titanium (Ti), zirconium (Zr), hafnium (Hf), vanadium (V), cobalt (Co), molybdenum (Mo), tungsten (W), aluminum (Al), arsenic (As), yttrium (Y), lanthanum (La), cerium (Ce), or lutetium (Lu);
L is independently alkyl, alkenyl, cycloalkyl, cycloheteroalkyl, arylalkyl, aryl or heteroaryl;
X is independently a hydrolysable ligand; and
1≤a≤2, b≥1,c≥1, and b+c≤5.

In some embodiments, M is selected from the group consisting of Sn, Bi, Sb, In, Te, and combinations thereof. In some embodiments, L is C1-C6 alkyl or C2-C6 alkenyl. In some embodiments, L is selected from the group consisting of propyl, isopropyl, butyl, iso-butyl, sec-butyl, tert-butyl, pentyl, isopentyl, sec-pentyl, tert-pentyl, hexyl, iso-hexyl, sec-hexyl, tert-hexyl, and combinations thereof. In some embodiments, L is fluorinated so that the alkyl or alkenyl group is substituted with one or more fluoro groups.

In some embodiments, X is any moiety readily reacting with a second compound to generate —OH, such as a moiety selected from the group consisting of amines, including dialkylamino and monoalkylamino; alkoxy; carboxylates, halogens, and sulfonates. In some embodiments, the sulfonate group is substituted with one or more amine groups. In some embodiments, the halide is one or more selected from the group consisting of F, Cl, Br, and I. In some embodiments, the sulfonate group includes a substituted or unsubstituted C1-C3 group.

In some embodiments, the second compound is at least one of an amine, a borane, a phosphine, or water. In some embodiments, the amine has a formula NₚHₙXₘ, where 0≤n≤3, 0≤m≤3, n+m=3 when p is 1, and n+m=4 when p is 2, and each X is independently a halogen selected from the group consisting of F, Cl, Br, and I. In some embodiments, the borane has a formula BₚHₙX_{m,} where 0≤n≤3, 0≤m≤3, n+m=3 when p is 1, and n+m=4 when p is 2, and each X is independently a halogen selected from the group consisting of F, Cl, Br, and I. In some embodiments, the phosphine has a formula PₚHₙXₘ, where 0≤n≤3, 0≤m≤3, n+m=3, when p is 1, or n+m=4 when p is 2, and each X is independently a halogen selected from the group consisting of F, Cl, Br, and I.

FIG. 7B illustrates a reaction between an organometallic compound 702 and water. As shown in FIG. 7B, in the presence of water, the organometallic compound 702 is hydrolyzed, that is, the hydroxyl replaces the hydrolysable ligand and bond to the core M, resulting in a hydroxyl-containing compound 704. More than one hydroxyl-containing compound 704 may undergo a condensation reaction to form an organometallic polymer 706. It is noted that while the organometallic polymer 706 includes three organometallic compounds 702, organometallic polymers with less or more organometallic compounds 702 are envisioned.

In some embodiments, the organometallic compound includes a sec-hexyl tris(dimethylamino) tin, t-hexyl tris(dimethylamino) tin, i-hexyl tris(dimethylamino) tin, n-hexyl tris(dimethylamino) tin, sec-pentyl tris(dimethylamino) tin, t-pentyl tris(dimethylamino) tin, i-pentyl tris(dimethylamino) tin, n-pentyl tris(dimethylamino) tin, sec-butyl tris(dimethylamino) tin, t-butyl tris(dimethylamino) tin, i-butyl tris(dimethylamino) tin, n-butyl tris(dimethylamino) tin, sec-butyl tris(dimethylamino) tin, i-propyl(tris) (dimethylamino) tin, n-propyl tris(diethylamino) tin, and analogous alkyl(tris)(t-butoxy) tin compounds, including sec-hexyl tris(t-butoxy) tin, t-hexyl tris(t-butoxy) tin, i-hexyl tris(t-butoxy) tin, n-hexyl tris(t-butoxy) tin, sec-pentyl tris(t-butoxy) tin, t-pentyl tris(t-butoxy) tin, i-pentyl tris(t-butoxy) tin, n-pentyl tris(t-butoxy) tin, t-butyl tris(t-butoxy) tin, i-butyl tris(butoxy) tin, n-butyl tris(butoxy) tin, sec-butyl tris(butoxy) tin, or n-propyl tris(butoxy) tin. In some embodiments, the organometallic compounds are fluorinated. In some embodiments, the organometallic compound has a boiling point less than about 200° C.

In some embodiments, the organometallic compound has one of the following structures:

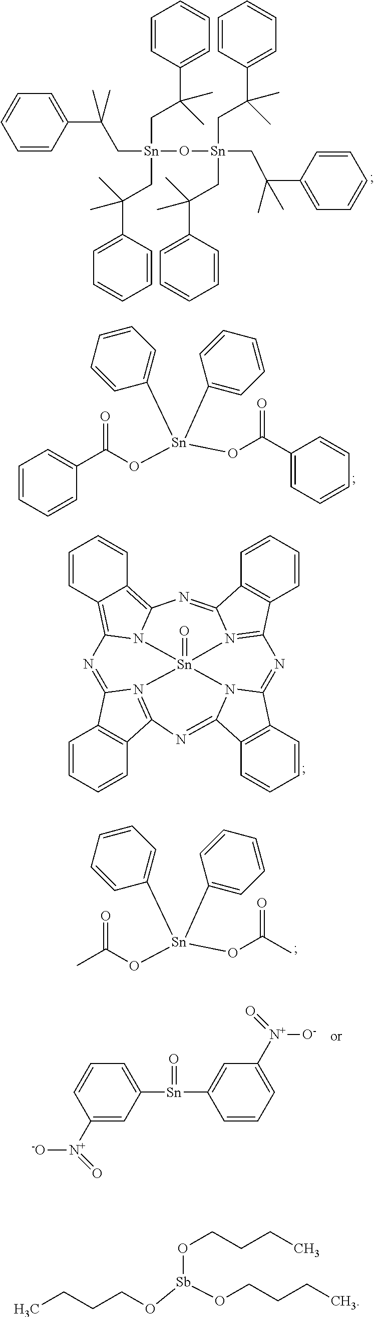

In some embodiments, the photoresist layer 230 is formed by applying a photoresist composition over the crosslinked resist underlayer 222 using, for example, spin coating. In some embodiments, the photoresist composition includes at least one kind of organometallic compounds and at least one kind of solvents. The amount of the organometallic compound in the photoresist composition may be from about 0.5 wt. % to 10 wt. % by weight. In some embodiments, the photoresist composition may include about 1 wt. % organometallic compound. In some other embodiments, the photoresist layer 230 is formed by depositing the organometallic compound using CVD, PVD or ALD.

In some embodiments, after the photoresist layer 230 is disposed over the crosslinked resist underlayer 222, a pre-exposure baking process may be performed to remove the solvent from the photoresist layer 230. In some embodiments, the pre-exposure baking process may be performed at a temperature of about 40° C. to about 140° C. for 10 seconds to 5 minutes. In some embodiments, the photoresist layer 230 is heated at a temperature of about 60° C. to about 120° C. for 20 seconds to 3 minutes.

Referring to FIGS. 1 and 2E, the method 100 proceeds to operation 110, in which the photoresist layer 230 is exposed to a radiation 240, in accordance with some embodiments. FIG. 2E is a cross-sectional view of the semiconductor device 200 after exposing the photoresist layer 230 to the radiation 240, in accordance with some embodiments.

The photoresist layer 230 is exposed to the radiation 240 from a light source through a photomask 250. The photomask 250 has a predefined pattern designed for an IC, based on a specification of the IC to be manufactured. The patterns of the photomask 250 correspond to patterns of materials that make up the various components of the IC device to be fabricated. For example, a portion of the IC design layout includes various IC features, such as an active region, gate electrode, source and drain, metal lines or vias of an interlayer interconnection, and openings for bonding pads, to be formed in the substrate 202.

In some embodiments, the photomask 250 includes first regions 252 and second regions 254. In the first regions 252, the radiation 240 is blocked by the photomask 250 to reach the photoresist layer 230, while in the second regions 254, the radiation 240 is not blocked by the photomask 250 and can pass through the photomask 250 to reach the photoresist layer 230. The selective exposure of the photoresist layer 230 proceeds through the photomask 250, thus forming exposed regions 230E and unexposed regions 230U in the photoresist layer 230.

In some embodiments, the radiation 240 is an EUV radiation (e.g., 13.5 nm). Alternatively, in some embodiments, the radiation 240 is a DUV radiation (e.g., from a 248 nm KrF excimer laser or a 193 nm ArF excimer laser), X-ray radiation, an e-beam radiation, an ion beam radiation, or other suitable radiations. In some embodiments, operation 110 is performed in a liquid (immersion lithography) or in a vacuum for EUV lithography and e-beam lithography.

In some embodiments, the exposed regions 230E of the photoresist layer 230 that are irradiated by the radiation 240 undergo a further condensation reaction to form metallic clusters while the unexposed regions 230U that are not irradiated by the radiation 240 do not undergo the condensation reaction. The exposed regions 230E of the photoresist layer 230 may constitute a latent pattern. As the metallic clusters are substantially insoluble in a developer used in a later development process, the exposed regions 220E of the photoresist layer 230 that are irradiated by the radiation 240 are substantially insoluble in the developer. The unexposed regions 230U that are not irradiated by the radiation 240 do not undergo condensation reaction and are soluble in the developer. The difference in solubility allows the latent pattern to be developed in the developing process.

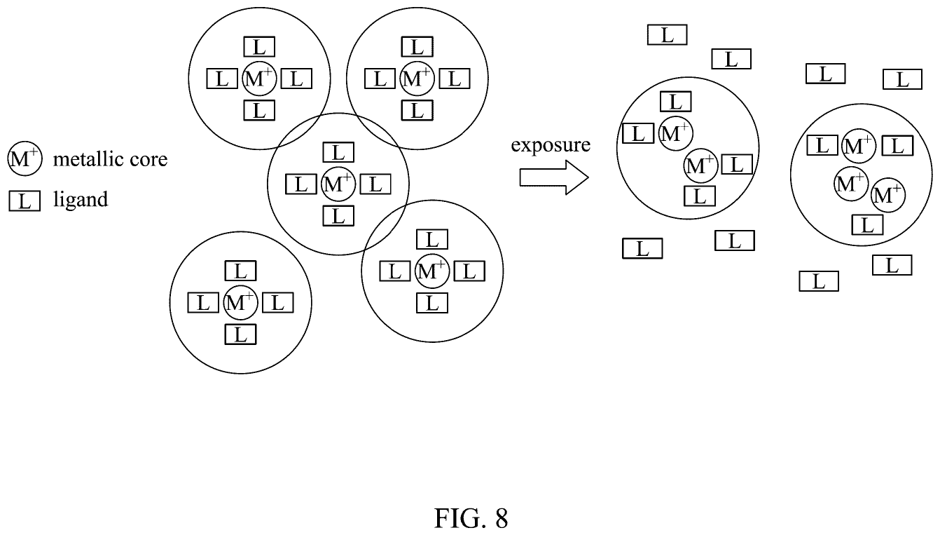

FIG. 8 shows a reaction that organometallic compounds undergo as a result of exposure to the radiation 240 in some embodiments. As a result of exposure to radiation 240, ligands L are cleaved from the metallic core M⁺ of the organometallic compounds, and two or more organometallic compound cores bond with each other to form the metal oxide cluster.

Subsequently, the photoresist layer 230 may be subjected to a post-exposure baking process. The post-exposure baking process may be performed at a temperature from about 80° C. to about 350° C. for a duration from about 60 seconds to about 360 seconds. The diffusion of the photoacid can be accelerated by the post-exposure baking process, which in turn accelerates the crosslinking reaction in the crosslinked resist underlayer 222.

Referring to FIGS. 1 and 2F, the method 100 proceeds to operation 112, in which the photoresist layer 230 is developed using a developer to form a patterned photoresist layer 230P, in accordance with some embodiments. FIG. 2F is a cross-sectional view of the semiconductor device of FIG. 2E after forming the patterned photoresist layer 230P.

During the developing process, the developer is applied to the photoresist layer 230. The developer removes the exposed or unexposed regions 230E, 230U depending on the resist type. For example and as shown in FIG. 2F, the photoresist layer 230 comprises a negative-type resist, so the exposed regions 230E are not dissolved by the developer and remain over the crosslinked resist underlayer 222 after the developing process. If the photoresist layer 230 comprises a positive-type resist, the exposed regions 230E would be dissolved by the developer, leaving the unexposed portions 230U over the crosslinked resist underlayer 222 after the developing process.

The remaining exposed regions 230E (or unexposed regions 230U) define a pattern in the patterned photoresist layer 230P. The pattern contains one or more openings that expose portions of the underlying crosslinked resist underlayer 222. Because of the small size of the organometallic oxide hydroxide clusters, the pattern in the patterned photoresist layer 230P is able to define features with pitches from about 24 nm to about 36 nm.

The developer may include alcohols, aromatic hydrocarbons, and the like. Examples of alcohols include, but are not limited to, methanol, ethanol, 1-butanol, and 4-Methyl-2-pentanol. Examples of aromatic hydrocarbons include, but are not limited to, xylene, toluene and benzene. In some embodiments, the developer is selected from at least one of methanol, 4-Methyl-2-pentanol and xylene.

The developer may be applied using any suitable methods. In some embodiments, the developer is applied by dipping the structure of FIG. 2E into a developer bath. In some embodiments, the developing solution is sprayed into the photoresist layer 230.

Referring to FIGS. 1 and 2G, the method 100 proceeds to operation 114, in which the crosslinked resist underlayer 222 is etched using the patterned photoresist layer 230P as an etch mask, in accordance with some embodiments. FIG. 2G is a cross-sectional view of the semiconductor device 200 of FIG. 2F after etching the crosslinked resist underlayer 222 using the patterned photoresist layer 230P as an etch mask.

Referring to FIG. 2G, the crosslinked resist underlayer 222 is etched, using the patterned photoresist layer 230P as an etch mask, to form a patterned crosslinked resist underlayer 222P. The etch can be a dry etch such as RIE or a wet etch. Etching of the crosslinked resist underlayer 222 exposes portions of the underlying material layer 210. If not completely consumed during the etching process, after etching the crosslinked resist underlayer 222, the patterned photoresist layer 230P is removed by, for example, stripping or oxygen plasma.

The presence of etching enhancement unit 314 in the crosslinked resist underlayer 222 increases the etching selectivity between the crosslinked resist underlayer 222 and the patterned photoresist layer 230P. As a result, the leakage window of the photoresist can be improved greater than 3%. Additionally, since the presence of etching enhancement unit 314 also increases the EUV absorption, the exposure dose (EOP) can be reduced greater than 3%. Accordingly, the resist underlayer compositions of the present disclosure help to improve the resist performance.

Referring to FIGS. 1 and 2H, the method 100 proceeds to operation 116, in which the material layer 210 is etched using the patterned crosslinked resist underlayer 222P as an etch mask, in accordance with some embodiments. FIG. 2H is a cross-sectional view of the semiconductor device 200 of FIG. 2G after etching the material layer 210 using the patterned crosslinked resist underlayer 222P as an etch mask.

Referring to FIG. 2H, the material layer 210 is etched, using the patterned crosslinked resist underlayer 222P as an etch mask, to form a patterned target layer 210P. Etching of the material layer 210 exposes portions of the underlying substrate 202

An etching process may be performed to transfer the pattern in the patterned crosslinked resist underlayer 222P to the material layer 210. In some embodiments, the etching process is an anisotropic etch such as a dry etch. In some embodiments, the dry etch is a RIE or a plasma etch.

One or more fabrication processes, such as an etching process or an implantation process, may be performed to the substrate 202 using the patterned crosslinked resist underlayer 222P and the patterned target layer 210P as a mask.

One aspect of this description relates to a resist underlayer composition. The resist underlayer composition includes a first polymer comprising a first polymer backbone and an etching resistance enhancement unit covalently bonded to the first polymer backbone via a first linker, wherein the etching resistance enhancement unit comprises a silicon-containing unit including silicon-oxygen bonds or a metal-containing unit including metal-oxygen bonds; a second polymer comprising a second polymer backbone and a crosslinker unit covalently bonded to the second polymer backbone via a second linker, wherein the crosslinker unit comprises one or more crosslinkable groups; an acid generator; and a solvent.

Another aspect of this description relates to a resist underlayer composition. The resist underlayer composition includes an acid generator; a solvent; and a copolymer having the following structure (III):

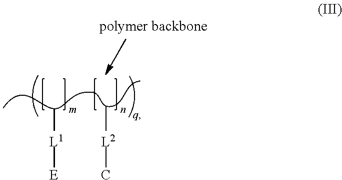

In the copolymer of structure (III), L¹ and L² are, at each occurrence, independently alkylene, alkenylene, alkynylene, heteroalkylene, heteroalkenylene, heteroalkynylene, cycloalkylene, heterocycloalkylene, arylene, heteroarylene or heteroatomic linkers. E is, at each occurrence, independently an etching resistance enhancement unit. C is, at each occurrence, independently a crosslinker unit comprising one or more crosslinkable groups. m, n and q are independently an integer of one or greater.

Still another aspect of this description relates to a method for forming a semiconductor device. The method includes forming a resist underlayer over a material layer on a substrate, the resist underlayer comprising a first polymer, a second polymer, and an acid generator. The first polymer includes a first polymer backbone and an etching resistance enhancement unit covalently bonded to the first polymer backbone via a first linker. The etching resistance enhancement unit includes a silicon-containing unit including silicon-oxygen bonds or a metal-containing unit including metal-oxygen bonds. The second polymer includes a second polymer backbone and a crosslinker unit covalently bonded to the second polymer backbone via a second linker. The crosslinker unit includes one or more crosslinkable groups. The method further includes performing a baking process to cause a crosslinking reaction of the crosslinking groups, thereby forming a crosslinked resist underlayer; depositing a photoresist layer comprising a metallic photoresist over the crosslinked resist underlayer; selectively exposing the photoresist layer to a patterning radiation; developing the selectively exposed photoresist layer to form a patterned photoresist layer; etching the crosslinked resist underlayer using the patterned photoresist layer as an etch mask to form a patterned crosslinked resist underlayer; and etching the material layer using the patterned crosslinked resist underlayer as an etch mask.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
forming a resist underlayer from a resist underlayer composition over a substrate,
forming a photoresist layer from a photoresist composition over the resist underlayer;
selectively exposing the photoresist layer to actinic radiation; and
developing the photoresist layer to form a pattern in the photoresist layer,
wherein the resist underlayer composition comprises a polymer having the following structure (III): 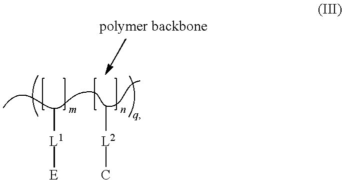
wherein:
L¹ and L² are, at each occurrence, independently alkylene, alkenylene, alkynylene, heteroalkylene, heteroalkenylene, heteroalkynylene, cycloalkylene, heterocycloalkylene, arylene, heteroarylene or heteroatomic linkers;
E is, at each occurrence, independently an etching resistance enhancement unit;
C is, at each occurrence, independently a crosslinker unit comprising one or more crosslinkable groups; and
m, n and q are independently an integer of one or greater.

2. The method of claim 1, wherein the etching resistance enhancement unit E is a silicon-containing unit derived from a silane, wherein the silane has one of the following structures: 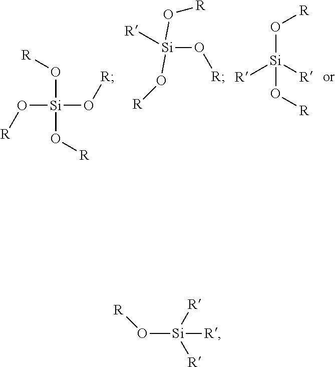
wherein R and R′ are, at each occurrence, independently C1-C12 alkyl or C2-C12 alkenyl, the C1-C12 alkyl or C2-C12 alkenyl is unsubstituted or substituted with one or more substituents selected from halogen, —SH, —PH₃, —PO₂, —C(═O)SH, —C(═O)OH, —OH, —NH₂, —C(═O)NH₂, —SO₂OH, —SO₂SH, —SOH, —SO₂, ether, ketone, ester, epoxy and phenyl.

3. The method of claim 1, wherein the etching resistance enhancement unit E is derived from a silsequioxane having one of the following structures: 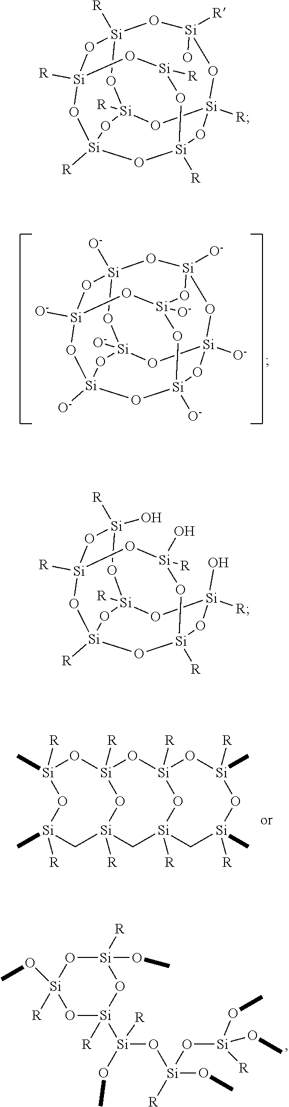
wherein R is, at each occurrence, independently C1-C12 alkyl or C2-C12 alkenyl, the C1-C12 alkyl or C2-C12 alkenyl is unsubstituted or substituted with one or more substituents selected from halogen, —SH, —PH₃, —PO₂, —C(═O)SH, —C(═O)OH, —OH, —NH₂, —C(═O)NH₂, —SO₂OH, —SO₂SH, —SOH, —SO₂, ether, ketone, ester, epoxy and phenyl.

4. The method of claim 1, wherein the etching resistance enhancement unit E is a metal-containing unit derived from an organometallic compound having the following structure: 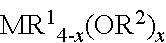
wherein:
M is a metal comprising tin (Sn), zinc (Zn), hafnium (Hf), titanium (Ti), zirconium (Zr), tungsten (W) or scandium (Sc);
R¹ and R² are independently C1-C12 alkyl; and
x is an integer from 0 to 4.

5. The method of claim 4, wherein the organometallic compound is SnR¹₃(OR²)₁, SnR¹₂(OR²)₂, SnR¹₁(OR²)₃, SnR²₄, HfR¹₃(OR²)₁, HfR¹₂(OR²)₂, HfR¹₁(OR²)₃, HfR²₄, ZnR¹₃(OR²)₁, ZnR¹₂(OR²)₂, ZnR¹₁(OR²)₃, or ZnR²₄, wherein R¹ and R² are each methyl.

6. The method of claim 1, wherein the crosslinker unit C comprises an aliphatic or aromatic group including one or more crosslinkable groups selected from epoxy, hydroxide, azo, alkyl halide, imine, alkene, alkyne, peroxide, ketone, aldehyde, allene, silane and heterocyclic groups.

7. The method of claim 6, wherein the crosslinker unit E has one of the following structures: 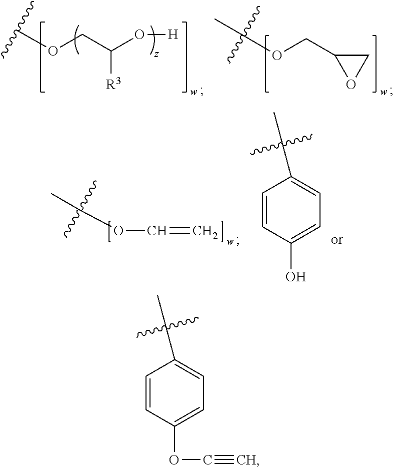
wherein:
R³ is, at each occurrence, H, alkyl, heteroalkyl, aryl, or heteroaryl;
z is an integer of 1 to 300; and
w is an integer of 1 to 6.

8. The method of claim 1, wherein the polymer of structure (IIII) has one of the following structures:

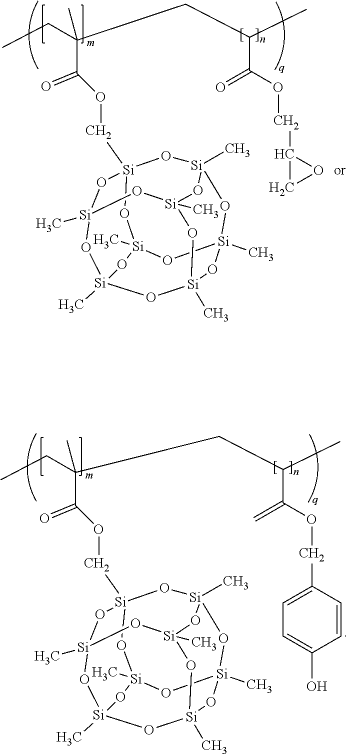

9. The method of claim 1, wherein the photoresist composition comprises a metal-containing photoresist.

10. The method of claim 9, wherein the metal-containing photoresist comprises an organometallic compound having the following structure: 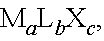
wherein:
M is at least one of tin (Sn), bismuth (Bi), antimony (Sb), indium (In), tellurium (Te), titanium (Ti), zirconium (Zr), hafnium (Hf), vanadium (V), cobalt (Co), molybdenum (Mo), tungsten (W), aluminum (Al), arsenic (As), yttrium (Y), lanthanum (La), cerium (Ce), or lutetium (Lu);
L is independently alkyl, alkenyl, cycloalkyl, cycloheteroalkyl, arylalkyl, aryl or heteroaryl;
X is independently a hydrolysable ligand; and
1≤a≤2, b≥1, c≥1, and b+c≤5.

11. A method for forming a semiconductor device, comprising:
forming a resist underlayer over a material layer on a substrate, the resist underlayer comprising a polymer having:
a polymer backbone;
first repeating units each having an etching resistance enhancement unit covalently bonded to the polymer backbone via a first linker, wherein the etching resistance enhancement unit comprises a silicon-containing unit including silicon-oxygen bonds or a metal-containing unit including metal-oxygen bonds; and
second repeating units each having a crosslinker unit covalently bonded to the polymer backbone via a second linker, wherein the crosslinker unit comprises one or more crosslinkable groups;
performing a baking process to cause a crosslinking reaction of the crosslinking groups, thereby forming a crosslinked resist underlayer;
depositing a photoresist layer comprising a metallic photoresist over the crosslinked resist underlayer;
selectively exposing the photoresist layer to a patterning radiation;
developing the selectively exposed photoresist layer to form a patterned photoresist layer;
etching the crosslinked resist underlayer using the patterned photoresist layer as an etch mask to form a patterned crosslinked resist underlayer; and
etching the material layer using the patterned crosslinked resist underlayer as an etch mask.

12. The method of claim 11, wherein the silicon-containing unit is derived from a compound having one of the following structures: 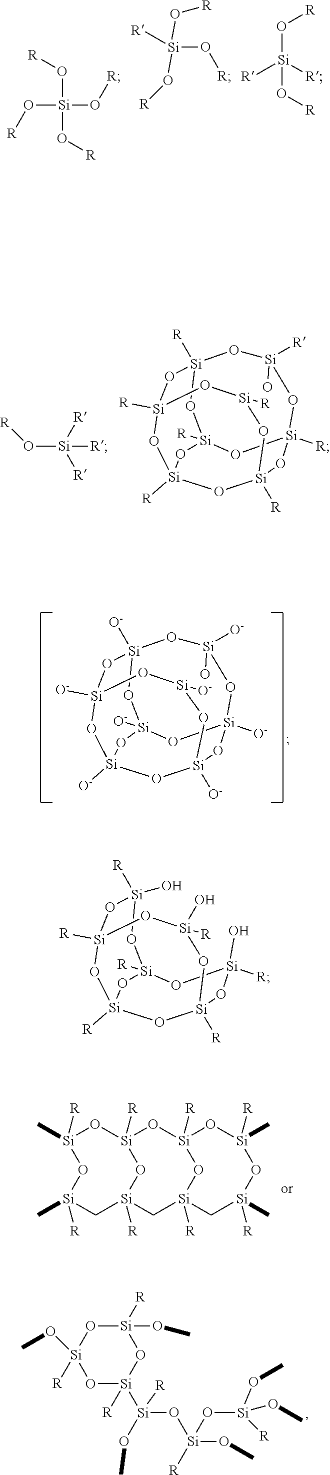
wherein R and R′ are, at each occurrence, independently C1-C12 alkyl or C2-C12 alkenyl group, the C1-C12 alkyl or C2-C12 alkenyl is unsubstituted or substituted with one or more substituents selected from halogen, —SH, —PH₃, —PO₂, —C(═O)SH, —C(═O)OH, —OH, —NH₂, —C(═O)NH₂, —SO₂OH, —SO₂SH, —SOH, —SO₂, ether, ketone, ester, epoxy and phenyl.

13. The method of claim 11, wherein the metal-containing unit is derived from an organometallic compound having the following structure: 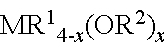
wherein:
M is a metal comprising tin (Sn), zinc (Zn), hafnium (Hf), titanium (Ti), zirconium (Zr), tungsten (W) or scandium (Sc);
R¹ and R² are independently C1-C12 alkyl; and
x is an integer from 0 to 4.

14. The method of claim 11, wherein the crosslinker unit has one of the following structures: 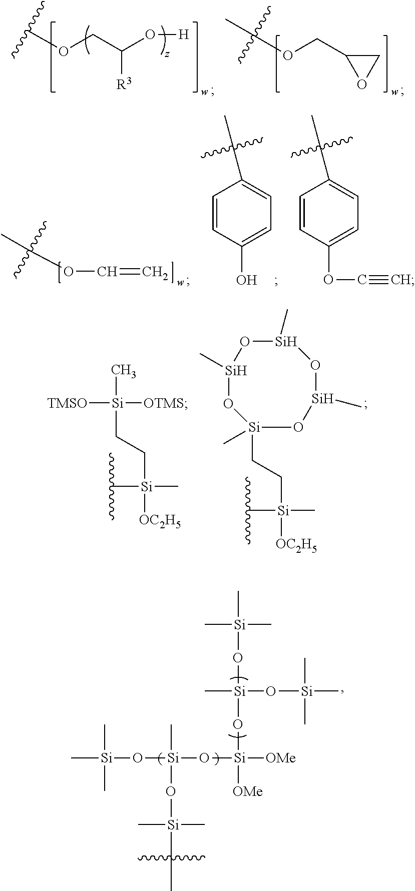
wherein:
R³is, at each occurrence, H, alkyl, heteroalkyl, aryl, or heteroaryl;
z is an integer of 1 to 300; and
w is an integer of 1 to 6.

15. The method of claim 11, wherein the polymer has one of the following structures:

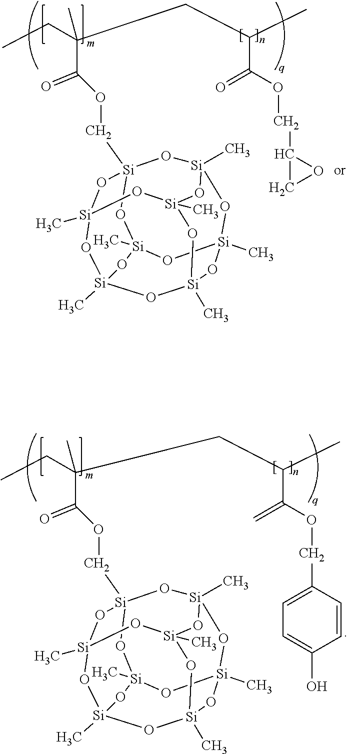

16. A method for forming a semiconductor device, comprising:
forming a material layer over a substrate;
applying a resist underlayer composition over the material layer to form a resist underlayer,
crosslinking the resist underlayer,
forming a photoresist layer comprising an organometallic compound over the resist underlayer; and
patterning the photoresist layer;
wherein the resist underlayer comprises a polymer having the following structure (III): 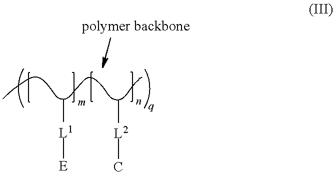
wherein:
L¹ and L² are, at each occurrence, independently alkylene, alkenylene, alkynylene, heteroalkylene, heteroalkenylene, heteroalkynylene, cycloalkylene, heterocycloalkylene, arylene, heteroarylene or heteroatomic linkers;
E is, at each occurrence, independently an etching resistance enhancement unit;
C is, at each occurrence, independently a crosslinker unit comprising one or more crosslinkable groups; and
m, n and q are independently an integer of one or greater.

17. The method of claim 16, wherein the etching resistance enhancement unit E has one of the following structures: 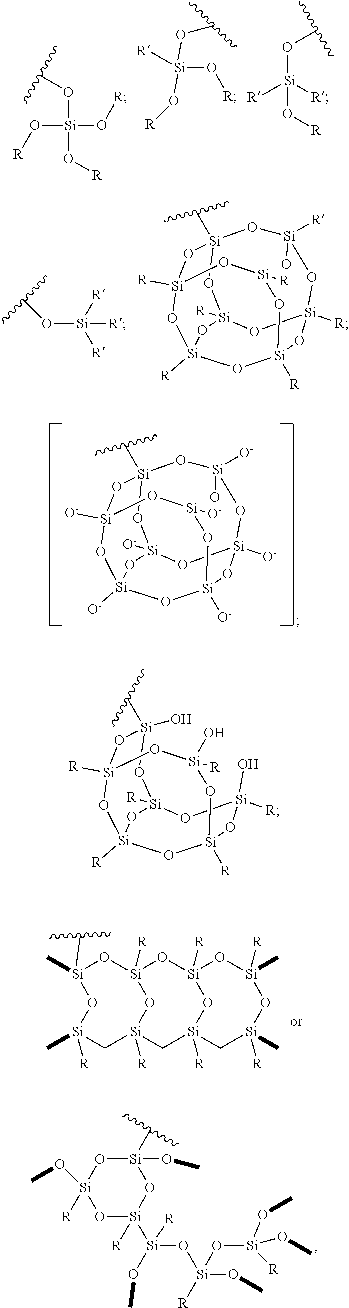
wherein:
R and R′ are, at each occurrence, independently C1-C12 alkyl or C2-C12 alkenyl; and
symbol “ [symbol] ” represents the bond to the linker L¹.

18. The method of claim 16, wherein the crosslinker unit C has one of the following structures: 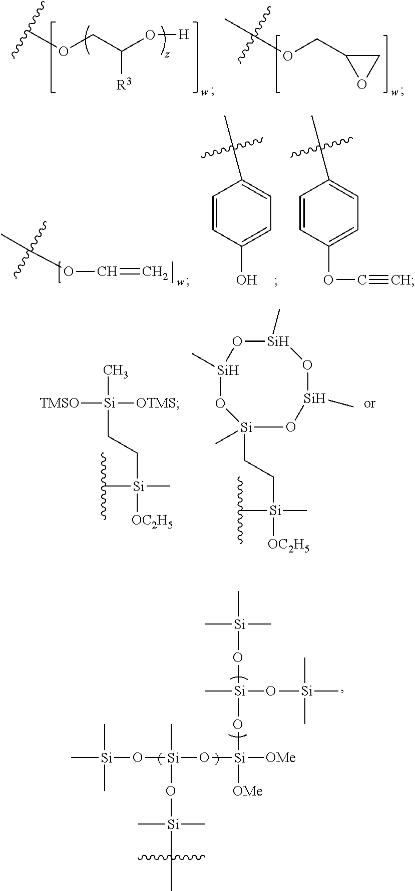
wherein:
R³ is, at each occurrence, H, alkyl, heteroalkyl, aryl, or heteroaryl;
z is an integer of 1 to 300; and
w is an integer of 1 to 6.

19. The method of claim 16, wherein L¹ has one of the following structures:

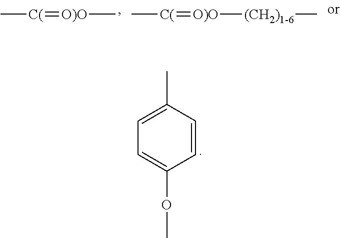

20. The method of claim 16, wherein L² has one of the following structures: [chemical structure]
